(19) United States
(12) Patent Application Publication
(10) Pub. No.: US 2025/0024730 A1
(43) Pub. Date: Jan. 16, 2025

(54) DISPLAY DEVICE

(71) Applicant: Samsung Display Co., LTD., Yongin-si (KR)

(72) Inventor: Hyung Guen YOON, Yongin-si (KR)

(73) Assignee: Samsung Display Co., LTD., Yongin-si (KR)

(21) Appl. No.: 18/768,733

(22) Filed: Jul. 10, 2024

(30) Foreign Application Priority Data
Jul. 11, 2023 (KR) 10-2023-0089967

(51) Int. Cl. H10K 59/38

(52) U.S. Cl. CPC H10K 59/38

(57) ABSTRACT

A display device includes a light emitting element; a color conversion layer that absorbs light emitted from the light emitting element and emits one of first color light, second color light, and third color light; a color filter layer that allows light emitted from the color conversion layer to selectively pass through the color filter layer; and an intermediate layer disposed between the color conversion layer and the color filter layer, that reflects a portion of the third color light to the color conversion layer, and transmits portions of the first and second color light to the color filter layer. The intermediate layer includes first, second, third, fourth and fifth layers. Each of the first, third, and fifth layers include a conductive material. Each of the second and fourth layers include a material different from that of the first, third, and fifth layers.

### CROSS-REFERENCE TO RELATED APPLICATION(S)

This application claims priority to and benefits of Korean patent application No. 10-2023-0089967 under 35 U.S.C. § 119 filed on Jul. 11, 2023 in the Korean Intellectual Property Office, the entire contents of which are incorporated herein by reference.

### BACKGROUND

### 1. Technical Field

Various embodiments disclosure relate to a display device.

### 2. Description of the Related Art

Recently, as interest in information display increases, research and development on display devices have been continuously conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Various embodiments may provide a display device having improved reliability.

An embodiment provides a display device that may include a light emitting element; a color conversion layer disposed on the light emitting element, the color conversion layer absorbing light emitted from the light emitting element and emitting one of first color light, second color light, and third color light; a color filter layer disposed on the color conversion layer, the color filter layer allowing light emitted from the color conversion layer to selectively pass through the color filter layer; and an intermediate layer disposed between the color conversion layer and the color filter layer, the intermediate layer reflecting a portion of the third color light to the color conversion layer, and transmitting a portion of the first color light and a portion of the second color light to the color filter layer. The intermediate layer may include a first layer, a second layer, a third layer, a fourth layer, and a fifth layer that are sequentially stacked each other. Each of the first layer, the third layer, and the fifth layer may include a conductive material. Each of the second layer and the fourth layer may include a material different from the material of each of the first layer, the third layer, and the fifth layer.

In an embodiment, each of the first layer, the third layer, and the fifth layer may include a metal thin-film with a thickness of about 30 nm or less. Each of the second layer and the fourth layer may include one of an organic insulating layer and an inorganic insulating layer.

In an embodiment, each of the second layer and the fourth layer may have a refractive index in a range of about 1.3 to about 2.5, and have a thickness of about 1 μm.

In an embodiment, the first layer, the second layer, the third layer, the fourth layer, and the fifth layer may have different thicknesses.

In an embodiment, the second layer and the fourth layer may have an identical thickness.

In an embodiment, the second layer and the fourth layer may have different thicknesses.

In an embodiment, one of the second layer and the fourth layer may have a thickness less than two times a thickness of another one of the second layer and the fourth layer.

In an embodiment, the first color light may include red light with a wavelength in a range of about 620 nm to about 680 nm. The second color light may include green light with a wavelength in a range of about 520 nm to about 580 nm. The third color light may include blue light with a wavelength in a range of about 420 nm to about 480 nm.

In an embodiment, the intermediate layer may reflect about 60% or more of the third color light to the color conversion layer, and transmit about 20% or less of the third color light to the color filter layer. The intermediate layer may transmit about 50% or more of the first color light to the color filter layer, absorb less than about 5% of the first color light, and reflect a rest of the first color light to the color conversion layer. The intermediate layer may transmit about 60% or more of the second color light to the color filter layer, absorb less than about 5% of the second color light, and reflect a rest of the second color light to the color conversion layer.

In an embodiment, the color conversion layer may include a first color conversion pattern including first color conversion particles that absorb light emitted from the light emitting element and emit the red light; a second color conversion pattern including second color conversion particles that absorb light emitted from the light emitting element and emit the green light; and a light scattering pattern including light scattering particles that absorb light emitted from the light emitting element and emit the blue light.

In an embodiment, the color filter layer may include a first color filter disposed on the first color conversion pattern; a second color filter disposed on the second color conversion pattern; and a third color filter disposed on the light scattering pattern. The first color filter may include a red color filter, the second color filter may include a green color filter, and the third color filter may include a blue color filter.

In an embodiment, the light emitting element may include an organic light emitting diode. The organic light emitting diode may include a pixel electrode disposed on a substrate, an emission layer disposed on the pixel electrode, and a common electrode disposed on the emission layer. One of the pixel electrode and the common electrode may include a transparent conductive material, and another one of the pixel electrode and the common electrode may include an opaque conductive material.

In an embodiment, the light emitting element may include a plurality of inorganic light emitting diodes each including a first end and a second end that face each other. The plurality of inorganic light emitting diodes may include a first semiconductor layer disposed in the second end and including an n-type semiconductor layer; a second semiconductor layer disposed in the first end and including a p-type semiconductor layer; and an active layer disposed between the first semiconductor layer and the second semiconductor layer.

In an embodiment, the display device may further include a first electrode electrically connected to the first end of each of the light emitting diodes; and a second electrode electrically connected to the second end of each of the light emitting diodes. Each of the first electrode and the second electrode may include a transparent conductive material.

In an embodiment, the display device may further include a low-reflective layer disposed on the color filter layer.

An embodiment provides a display device that may include a light emitting element; a color conversion layer disposed on the light emitting element, the color conversion layer absorbing light emitted from the light emitting element and emitting one of first color light, second color light, and third color light; a color filter layer disposed on the color conversion layer, the color filter layer allowing light emitted from the color conversion layer to selectively pass through the color filter layer; and a cover layer disposed between the color conversion layer and the color filter layer. The cover layer may include a plurality of sub-insulating layers, each including a first sub-layer and a second sub-layer. The first sub-layer and the second sub-layer may have a different refractive index.

In an embodiment, the second sub-layer may be disposed on the first sub-layer. The first sub-layer may include a first inorganic layer with a first refractive index, and the second sub-layer may include a second inorganic layer with a second refractive index. The first refractive index may be greater than the second refractive index.

In an embodiment, the first sub-layer may be disposed on the second sub-layer. The first sub-layer may include a first inorganic layer with a first refractive index, and the second sub-layer may include a second inorganic layer with a second refractive index. The second refractive index may be less than the first refractive index.

An embodiment provides a display device that may include a light emitting element; a color conversion layer disposed on the light emitting element, the color conversion layer absorbing light emitted from the light emitting element and emitting one of first color light, second color light, and third color light; an intermediate layer disposed on the color conversion layer, the intermediate layer reflecting a portion of the third color light to the color conversion layer, and allowing a portion of the first color light and a portion of the second color light to pass though the color conversion layer; an anti-reflection film disposed on the intermediate layer. The intermediate layer may include a first layer, a second layer, a third layer, a fourth layer, and a fifth layer that are sequentially stacked each other. Each of the first layer, the third layer, and the fifth layer may include a conductive material. Each of the second layer and the fourth layer may include a material different from the material of each of the first layer, the third layer, and the fifth layer.

In an embodiment, each of the first layer, the third layer, and the fifth layer may include a metal thin-film with a thickness of about 30 nm or less. Each of the second layer and the fourth layer may include one of an organic insulating layer and an inorganic insulating layer.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device in accordance with an embodiment.

FIG. 2 is a schematic sectional view illustrating a display panel of FIG. 1.

FIG. 3 is a schematic circuit diagram illustrating an electrical connection relationship of components included in each of pixels illustrated in FIG. 1.

FIG. 4 is a schematic sectional view taken along line I-I′ of FIG. 1.

FIG. 5 is a schematic enlarged view of portion EA1 of FIG. 4.

FIG. 6A is a graph depicting simulation results of light emitted from an intermediate layer disposed on a first color conversion pattern of FIG. 4.

FIG. 6B is a graph depicting simulation results of light emitted from an intermediate layer disposed on a second color conversion pattern of FIG. 4.

FIG. 7 illustrates a pixel in accordance with an embodiment, and is a schematic sectional view corresponding to line I-I′ of FIG. 1.

FIG. 8 illustrates a pixel in accordance with an embodiment, and is a schematic sectional view corresponding to line I-I′ of FIG. 1.

FIG. 9 illustrates a pixel in accordance with an embodiment, and is a schematic sectional view corresponding to line I-I′ of FIG. 1.

FIGS. 10 and 11 are schematic enlarged views illustrating portion EA2 of FIG. 9.

FIG. 12 is a graph illustrating the reflectance of light passing through a cover layer of FIG. 10.

FIG. 13 is a schematic circuit diagram illustrating an electrical connection relationship of components included in each of pixels illustrated in FIG. 1.

FIG. 14 is a schematic perspective view illustrating a light emitting element of FIG. 13.

FIG. 15 is a schematic sectional view illustrating a light emitting element of FIG. 14.

FIG. 16 is a schematic sectional view taken along line I-I′ of FIG. 1.

### DETAILED DESCRIPTION OF THE EMBODIMENTS

As the disclosure allows for various changes and numerous embodiments, embodiments will be illustrated in the drawings and described in detail in the written description. However, this is not intended to limit the disclosure to given modes of practice, and it is to be appreciated that all changes, equivalents, and substitutes that do not depart from the technical scope of the disclosure are encompassed in the disclosure.

Throughout the disclosure, like reference numerals refer to like parts throughout the various figures and embodiments of the disclosure. The sizes of elements in the accompanying drawings may be exaggerated for clarity of illustration.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

Furthermore, in case that a first part such as a layer, a film, a region, or a plate is disposed on a second part, the first part may be not only directly on the second part but a third part may intervene between them. For example, in case that it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be not only directly under the second part but a third part may intervene between them.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

It will be understood that when an element (for example, a first element) is referred to as being (operatively or communicatively) “coupled with/to,” or “connected with/to” another element (for example, a second element), the first element can be coupled or connected with/to the second element directly or via another element (for example, a third element). In contrast, it will be understood that when an element (for example, a first element) is referred to as being “directly coupled with/to” or “directly connected with/to” another element (for example, a second element), no other element (for example, a third element) intervenes between the element and the other element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments and details are described with reference to the accompanying drawings in order to describe the disclosure in detail so that those having ordinary skill in the art to which the disclosure pertains can practice the disclosure.

As used herein, the singular forms, “a,” “an,” and “the” are intended to include the plural forms as well, unless the context clearly indicates otherwise.

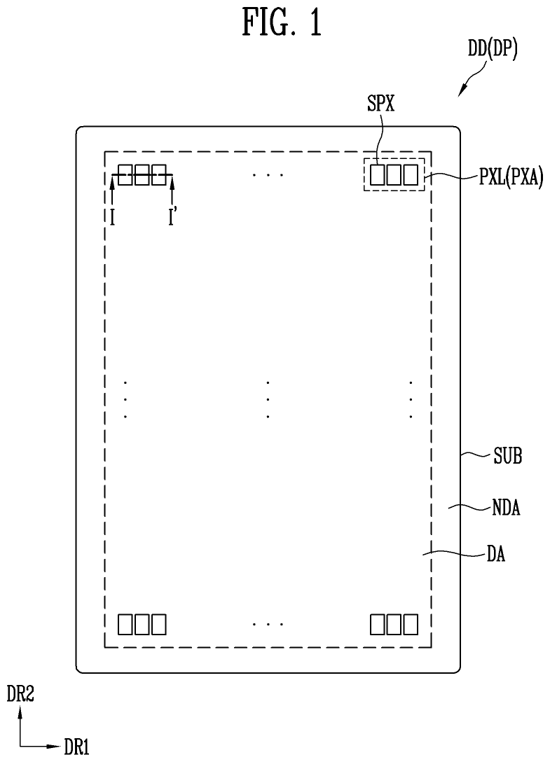

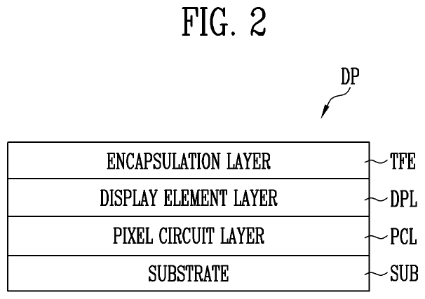

FIG. 1 is a schematic plan view illustrating a display device DD in accordance with an embodiment. FIG. 2 is a schematic sectional view illustrating a display panel DP of FIG. 1.

In FIGS. 1 and 2, for the convenience sake, there is schematically illustrated the display device DD, for example, the structure of a display panel DP provided in the display device DD, centered on a display area DA in which an image is displayed.

Referring to FIGS. 1 and 2, the display panel DP (or the display device DD) in accordance with an embodiment may be provided in various shapes. For example, the display panel DP may be provided in the form of a rectangle including two pairs of sides parallel to each other. However, the disclosure is not limited to the foregoing embodiment. In the case where the display panel DP is provided in the form of a rectangular plate, one pair of sides of the two pairs of sides may be longer than the other.

At least a portion of the display panel DP may have flexibility, and the display panel DP may be folded on the portion having the flexibility, but the disclosure is not limited thereto.

The display panel DP may display an image. A self-emissive display panel, such as an organic light emitting display panel (OLED panel) using an organic light emitting diode as a light emitting element, a subminiature light emitting diode (micro-LED or nano-LED) display panel using a subminiature LD as a light emitting element, and a quantum dot organic light emitting display panel (QD OLED panel) using a quantum dot and an organic light emitting diode, may be used as the display panel DP. For example, a non-emissive display panel such as a liquid crystal display (LCD) panel, an electro-phoretic display (EPD) panel, or an electro-wetting display (EWD) panel may be used as the display panel DP. In case that the non-emissive display panel is used as the display panel DP, the display device DD may include a backlight unit configured to supply light to the display panel DP.

The display panel DP may include a substrate SUB, and pixels PXL provided on the substrate SUB.

The substrate SUB may include transparent insulating material to allow light transmission, but is not limited thereto. The substrate SUB may be a rigid substrate or a flexible substrate.

For example, the rigid substrate may be one of a glass substrate, a quartz substrate, a glass ceramic substrate, and a crystalline glass substrate, but is not limited thereto.

The flexible substrate may be either a film substrate or a plastic substrate which includes polymer organic material. For example, the flexible substrate SUB may include at least one of the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

One area or an area of the substrate SUB may be provided as the display area DA in which the pixels PXL are disposed, and the other area of the substrate SUB may be provided as the non-display area NDA. For example, the substrate SUB may include the display area DA including pixel areas PXA on which the respective pixels PXL are disposed, and the non-display area NDA disposed around a perimeter of the display area DA (or adjacent to the display area DA).

The non-display area NDA may be disposed adjacent to the display area DA. The non-display area NDA may be provided on at least one side or a side of the display area DA. For example, the non-display area NDA may enclose the perimeter (or edges) of the display area DA. A line component connected to each of the pixels PXL, and a driver connected to the line component and configured to drive the pixel PXL may be provided in the non-display area NDA.

Each of the pixels PXL may be provided in the display area DA of the substrate SUB. Each of the pixels PXL may include a light emitting element which emits white light and/or color light, and a pixel circuit configured to drive the light emitting element. The pixel circuit may include at least one transistor which is electrically connected to the light emitting element. Each pixel PXL may emit light of any one color among red, green, and blue, and it is not limited thereto. Each pixel PXL may emit light of any one color among cyan, magenta, yellow, and white.

The pixels PXL may be arranged or disposed in a matrix form along pixel rows extending in a first direction DR1 and pixel columns extending in a second direction DR2 intersecting with the first direction DR1. However, the arrangement of the pixels PXL is not limited to a selectable arrangement. In other words, the pixels PXL may be arranged or disposed in various forms. Furthermore, in case that pixels PXL are provided, the pixels PXL may have different surface areas (or different sizes). For example, in case that pixels PXL emit different colors of light, the pixels PXL may have different surface areas (or different sizes) or different shapes by colors.

The driver may provide a given signal and a given voltage to each pixel PXL through the line component to control the operation of the pixel PXL.

The display panel DP (or each of the pixels PXL) may include a pixel circuit layer PCL, a display element layer DPL, and an encapsulation layer TFE which are successively disposed on the substrate SUB.

The pixel circuit layer PCL may be provided on the substrate SUB, and include a transistor and signal lines connected to the transistor. For example, the transistor may have a shape in which an active pattern (or a semiconductor pattern), a gate electrode, a source electrode, and a drain electrode are successively stacked with insulating layers interposed therebetween. The semiconductor pattern may include amorphous silicon, poly silicon, low temperature poly silicon, and an organic semiconductor, and/or an oxide semiconductor. Although the gate electrode, the source electrode, and the drain electrode each may include one of aluminum (Al), copper (Cu), titanium (Ti), and molybdenum (Mo), the embodiments are not limited thereto. For example, the pixel circuit layer PCL may include at least one or more insulating layers.

The display element layer DPL may be disposed on the pixel circuit layer PCL. The display element layer DPL may include a light emitting element configured to emit light. Although the light emitting element may be, for example, an organic light emitting diode, the embodiments are not limited thereto. In an embodiment, the light emitting element may be an inorganic light emitting element including inorganic light emitting material, or a light emitting element that emits light after changing the wavelength of the light to be emitted using quantum dots.

The encapsulation layer TFE may be disposed on the display element layer DPL. The encapsulation layer TFE may be an encapsulation substrate or have the form of an encapsulation film having a multilayer structure. In case that the encapsulation layer TFE has the form of the encapsulation film, the encapsulation layer TFE may include an inorganic layer and/or an organic layer. For example, the encapsulation layer TFE may have a structure formed by successively stacking an inorganic layer, an organic layer, and an inorganic layer. The encapsulation layer TFE may prevent external air or water from permeating the display element layer DPL or the pixel circuit layer PCL.

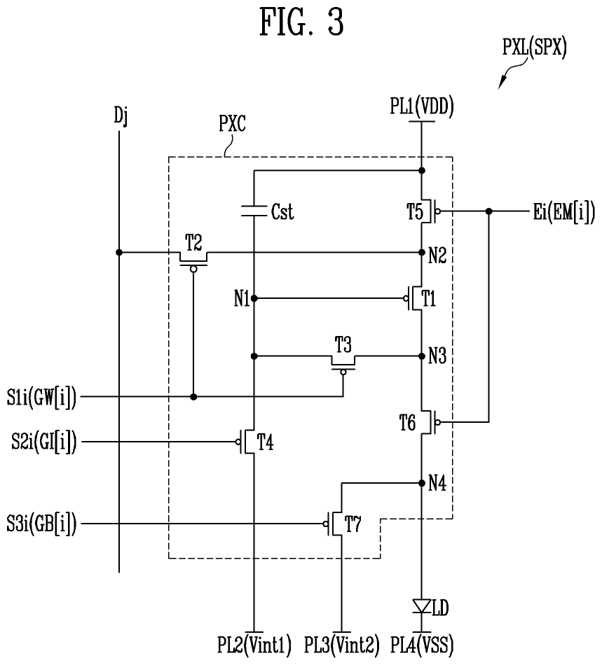

FIG. 3 is a schematic circuit diagram illustrating an electrical connection relationship of components included in each of pixels PXL illustrated in FIG. 1. For convenience of description, FIG. 3 illustrates a pixel PXL (or a sub-pixel SPX) that is positioned on an i-th horizontal line (or an i-th pixel row) and connected to the j-th data line Dj.

Referring to FIGS. 1 to 3, the pixel PXL (or the sub-pixel SPX) may include a pixel circuit PXC and a light emitting element LD. The pixel circuit PXC may include first, second, third, fourth, fifth, sixths, and seventh transistors T1, T2, T3, T4, T5, T6, and T7, and a storage capacitor Cst.

A first electrode (or a pixel electrode) of the light emitting element may be connected to a fourth node N4, and a second electrode (or a common electrode) thereof may be connected to a fourth power line PL4. The light emitting element LD may emit light of a given luminance corresponding to the amount of current (or driving current) supplied from the first transistor T1. In an embodiment, the light emitting element LD may be an organic light emitting diode including an organic light emitting layer. However, the embodiments are not limited to the aforementioned embodiment. In an embodiment, the light emitting element LD may be an inorganic light emitting diode formed of inorganic material, or a light emitting diode formed of a combination of inorganic material and organic material.

The first transistor T1 (or a driving transistor) may be electrically connected between a first power line PL1 and the first electrode of the light emitting element LD. The first transistor T1 may include a gate electrode electrically connected to a first node N1. The first transistor T1 may control, in response to the voltage of the first node N1, the amount of current (or driving current) flowing from the first power line PL1 to the fourth power line PL4 via the light emitting element LD. A first power voltage VDD may be provided to the first power line PL1. A second power voltage VSS may be provided to the fourth power line PL4. The first power voltage VDD may be set to a voltage higher than the second power voltage VSS.

The second transistor T2 may be electrically connected between the j-th data line Dj and a second node N2. A gate electrode of the second transistor T2 may be connected to a 1i-th scan line S1i (or a first scan line). In case that a first scan signal GW[i] (for example, a first scan signal of a low level) is supplied to the 1i-th scan line S1i, the second transistor T2 may be turned on to electrically connect the j-th data line Dj to the second node N2. In the case where each of the first transistor T1 and the third transistor T3 is turned on, the second transistor T2 may transmit a data signal of the j-th data line Dj to the first node N1 in response to the first scan signal GW[i].

The third transistor T3 may be electrically connected between the first node N1 and a third node N3. A gate electrode of the third transistor T3 may be electrically connected to the 1i-th scan line S1i. The third transistor T3 may be turned on in case that the first scan signal GW[i] is supplied to the 1i-th scan line S1i. If the third transistor T3 is turned on, the first transistor T1 may have a diode-connected form.

The fourth transistor T4 may be electrically connected between the first node N1 and the second power line PL2. A gate electrode of the fourth transistor T4 may be electrically connected to a 2i-th scan line S2i (or a second scan line). A first initialization power voltage Vint1 may be provided to the second power line PL2. The fourth transistor T4 may be turned on by a second scan signal GI[i] supplied to the 2i-th scan line S2i. If the fourth transistor T4 is turned on, the first initialization power voltage Vint1 may be supplied to the first node N1 (for example, the gate electrode of the first transistor T1).

The fifth transistor T5 may be electrically connected between the first power line PL1 and the second node N2. A gate electrode of the fifth transistor T5 may be electrically connected to an i-th emission control line Ei (or an emission control line). The sixth transistor T6 may be electrically connected between the third node N3 and the light emitting element LD (or the fourth node N4). A gate electrode of the sixth transistor T6 may be electrically connected to the i-th emission control line Ei. The fifth transistor T5 and the sixth transistor T6 may be turned off in case that an emission control signal EM[i] (for example, an emission control signal EM[i] of a high level) is supplied to the i-th emission control line Ei, and may be turned on in the other cases.

The seventh transistor T7 may be electrically connected between the first electrode (for example, the fourth node N4) of the light emitting element LD and a third power line PL3. A gate electrode of the seventh transistor T7 may be electrically connected to a 3i-th scan line S3i. A second initialization power voltage Vint2 may be provided to the third power line PL3. In an embodiment, the second initialization power voltage Vint2 may be the same as or different from the first initialization power voltage Vint1. The seventh transistor T7 may be turned on by a third scan signal GB[i] supplied to the 3i-th scan line S3i to supply the second initialization power voltage Vint2 to the first electrode of the light emitting element LD.

The storage capacitor Cst may be connected or formed between the first power line PL1 and the first node N1.

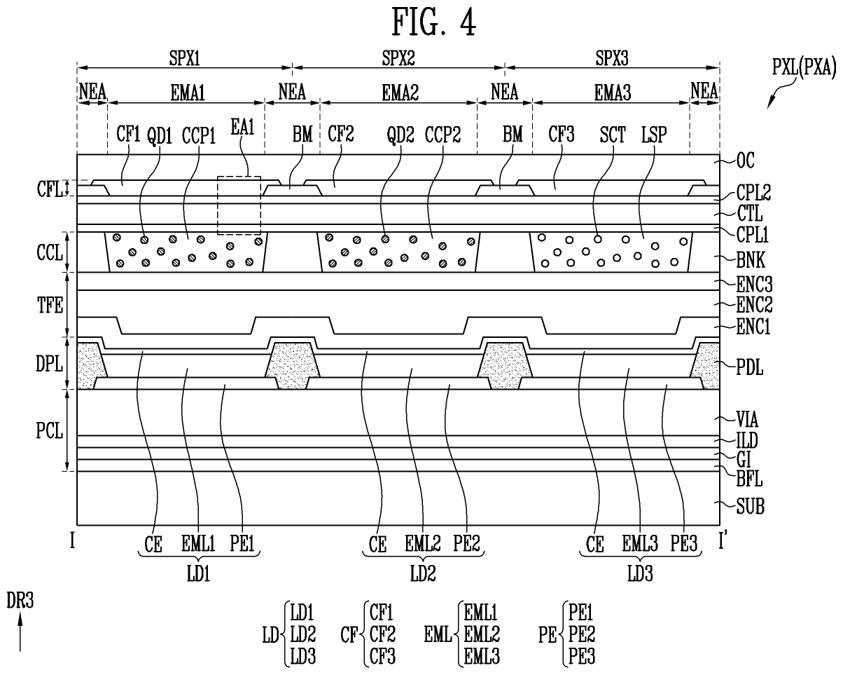

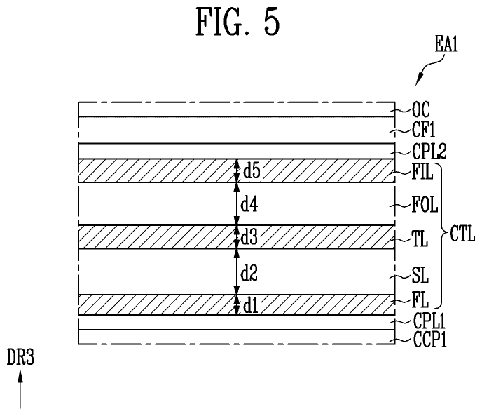

FIG. 4 is a schematic sectional view taken along line I-I′ of FIG. 1. FIG. 5 is a schematic enlarged view of portion EA1 of FIG. 4.

In FIG. 4, the term “pixel PXL” encompasses not only the components included in the pixel PXL but also an area in which the components are provided (or positioned).

Referring to FIGS. 1 to 5, the pixel PXL may be disposed in a pixel area PXA in the display area DA. The pixel area PXA may include an emission area and a non-emission area NEA.

The pixel PXL may include a first sub-pixel SPX1, a second sub-pixel SPX2, and a third sub-pixel SPX3. The first sub-pixel SPX1 may emit red light (or light of a first color). The second sub-pixel SPX2 may emit green light (or light of a second color). The third sub-pixel SPX3 may emit blue light (or light of a third color). The embodiments are not limited to the aforementioned example.

The first sub-pixel SPX1 may include a first emission area EMA1 and a non-emission area NEA which is adjacent to the first emission area EMA1 (or encloses at least one side or a side of the first emission area EMA1). The second sub-pixel SPX2 may include a second emission area EMA2 and a non-emission area NEA which is adjacent to the second emission area EMA2 (or encloses at least one side or a side of the second emission area EMA2). The third sub-pixel SPX3 may include a third emission area EMA3 and a non-emission area NEA which is adjacent to the third emission area EMA3 (or encloses at least one side or a side of the third emission area EMA3). The first emission area EMA1, the second emission area EMA2, and the third emission area EMA3 may form the emission area of the pixel PXL.

Each of the first, second, and third sub-pixels SPX1, SPX2, and SPX3 may include a light emitting element LD configured to emit light, and circuit elements configured to drive the light emitting element LD. The first emission area EMA1 may be an area where light is emitted from the light emitting element LD that is driven by the circuit elements of the first sub-pixel circuit SPX1. The second emission area EMA2 may be an area where light is emitted from the light emitting element LD that is driven by the circuit elements of the second sub-pixel circuit SPX2. The third emission area EMA3 may be an area where light is emitted from the light emitting element LD that is driven by the circuit elements of the third sub-pixel circuit SPX3.

Each of the first to third sub-pixels SPX1, SPX2, and SPX3 may include a substrate SUB, a pixel circuit layer PCL, a display element layer DPL, an encapsulation layer TFE, a color conversion layer CCL, an intermediate layer CTL, and a color filter layer CFL.

The pixel circuit layer PCL and the display element layer DPL may be disposed on one surface or a surface of the substrate SUB and overlap each other. For example, the pixel area PXA of the substrate SUB may include the pixel circuit layer PCL disposed on one surface or a surface of the substrate SUB, and the display element layer DPL disposed on the pixel circuit layer PCL. However, relative positions of the pixel circuit layer PCL and the display element layer DPL on the substrate SUB may be changed depending on embodiments.

The substrate SUB may include transparent insulating material to allow light transmission. The substrate SUB may be a rigid substrate or a flexible substrate.

In the pixel circuit layer PCL, circuit elements that form the pixel circuit (refer to “PXC” in FIG. 3) of each of the first to third sub-pixels SPX1, SPX2, and SPX3, and signal lines electrically connected to the circuit elements, may be disposed. At least one or more insulating layers may be disposed in the pixel circuit layer PCL. For example, a buffer layer BFL, a gate insulating layer GI, an interlayer insulating layer ILD, and a via layer VIA may be disposed in the pixel circuit layer PCL.

The buffer layer BFL may be disposed on the overall surface of the substrate SUB. The buffer layer BFL may prevent impurities from diffusing into the transistors included in the pixel circuit PXC, for example, the first to seventh transistors (refer to “T1 to T7” in FIG. 3). The buffer layer BFL may be an inorganic insulating layer including inorganic material (or substance). The buffer layer BFL may include at least one of silicon nitride (SiNₓ), silicon oxide (SiOₓ), silicon oxynitride (SiOₓN_{y}), or include at least one of metal oxides such as aluminum oxide (AlₓO_{y}). Although the buffer layer BFL may be provided in a single-layer structure, the buffer layer BFL may be provided in a multilayer structure having at least two or more layers. In the case where the buffer layer BFL has a multilayer structure, the respective layers may be formed of a same material or different materials. The buffer layer BFL may be omitted depending on the material of the substrate SUB or processing conditions.

The gate insulating layer GI may be disposed on the overall surface of the buffer layer BFL. The gate insulating layer GI may include a same material as that of the buffer layer BFL, or include a suitable (or selected) material among the materials as the constituent materials of the buffer layer BFL. For example, the gate insulating layer GI may include an inorganic insulating layer including inorganic material. In an embodiment, the gate insulating layer GI may be partially disposed on the buffer layer BFL.

The interlayer insulating layer ILD may be provided and/or formed on the overall surface of the gate insulating layer GI. The interlayer insulating layer ILD may include a same material as that of the buffer layer BFL, or include one or more suitable (or selected) materials among the materials as the constituent materials of the buffer layer BFL.

The via layer VIA may be provided and/or formed on the overall surface of the interlayer insulating layer ILD. The via layer VIA may be an inorganic insulating layer including inorganic material or an organic insulating layer including organic material. The inorganic insulating layer may include, for example, at least one of silicon oxide (SiOₓ), silicon nitride (SiNₓ), silicon oxynitride (SiOₓN_{y}), and aluminum oxide (AlOₓ). The organic insulating layer may include, for example, at least one of polyacrylic resin, epoxy resin, phenolic resin, polyamide resin, polyimide rein, unsaturated polyester resin, poly-phenylen ether resin, poly-phenylene sulfide resin, and benzocyclobutene resin. In an embodiment, the via layer VIA may be formed of an organic insulating layer including organic material.

The display element layer DPL may be disposed on the pixel circuit layer PCL (or the via layer VIA).

The light emitting element LD and a pixel defining layer PDL may be disposed in the display element layer DPL.

The light emitting elements LD may include a first light emitting element LD1, a second light emitting element LD2, and a third light emitting element LD3. The first light emitting element LD1 may be disposed in the display element layer DPL of the first sub-pixel SPX1. The second light emitting element LD2 may be disposed in the display element layer DPL of the second sub-pixel SPX2. The third light emitting element LD3 may be disposed in the display element layer DPL of the third sub-pixel SPX3.

The first light emitting element LD1 may include a first pixel electrode PE1 (an anode electrode or a first electrode), a first emission layer EML1, and a common electrode CE (a cathode electrode or a second electrode). The second light emitting element LD2 may include a second pixel electrode PE2 (an anode electrode or a first electrode), a second emission layer EML2, and the common electrode CE (the cathode electrode or the second electrode). The third light emitting element LD3 may include a third pixel electrode PE3 (an anode electrode or a first electrode), a third emission layer EML3, and the common electrode CE (the cathode electrode or the second electrode). Each of the first, second, and third light emitting elements LD1, LD2, and LD3 may be electrically connected to the pixel circuit PXC of the corresponding sub-pixel (refer to “SPX” in FIG. 3).

The first pixel electrode PEI may be provided and/or formed on the via layer VIA of the first sub-pixel SPX1. The second pixel electrode PE2 may be provided and/or formed on the via layer VIA of the second sub-pixel SPX2. The third pixel electrode PE3 may be provided and/or formed on the via layer VIA of the third sub-pixel SPX3. The first pixel electrode PE1, the second pixel electrode PE2, and the third pixel electrode PE3 may form the pixel electrode PE of the pixel PXL. Each of the first, second, and third pixel electrodes PE1, PE2, and PE3 may be electrically connected to the transistor disposed in the pixel circuit layer PCL, through a contact hole passing through insulating layers disposed in the pixel circuit layer PCL.

Each of the first pixel electrode PE1, the second pixel electrode PE2, and the third pixel electrode PE3 may be formed of conductive material (or substance). The conductive material may include opaque metal. For example, the opaque metal may include metal such as silver (Ag), magnesium (Mg), aluminum (Al), platinum (Pt), palladium (Pd), gold (Au), nickel (Ni), neodymium (Nd), iridium (Ir), chrome (Cr), titanium (Ti), and an alloy thereof. The material of each of the first pixel electrode PE1, the second pixel electrode PE2, and the third pixel electrode PE3 are not limited to those of the aforementioned embodiment. In an embodiment, each of the first pixel electrode PE1, the second pixel electrode PE2, and the third pixel electrode PE3 may include transparent conductive material (or substance). The transparent conductive material (or substance) may include transparent conductive oxides such as indium tin oxide (ITO), indium zinc oxide (IZO), zinc oxide (ZnOₓ), indium gallium zinc oxide (IGZO), and indium tin zinc oxide (ITZO), and a conductive polymer such as PEDOT (poly (3,4-ethylenedioxythiophene)). In the case where each of the first pixel electrode PE1, the second pixel electrode PE2, and the third pixel electrode PE3 includes transparent conductive material (or substance), a separate conductive layer made of opaque metal for reflecting light emitted from the first emission layer EML1, the second emission layer EML2, and the third emission layer EML3 in an image display direction of the display device DD (or an upward direction of the encapsulation layer TFE) may be provided.

The first pixel electrode PE1 may be positioned in at least the first emission area EMA1. The second pixel electrode PE2 may be positioned in at least the second emission area EMA2. The third pixel electrode PE3 may be positioned in at least the third emission area EMA3. The first pixel electrode PE1, the second pixel electrode PE2, and the third pixel electrode PE3 may be spaced apart from each other on the via layer VIA.

The pixel defining layer PDL may be provided on the pixel circuit layer PCL (or the via layer VIA) in the non-emission area NEA, and may define (or partition) the first emission area EMA1, the second emission area EMA2, and the third emission area EMA3. The pixel-defining layer PDL may include an organic insulating layer made of an organic material. The organic material may include acryl resin, epoxy resin, phenolic resin, polyamide resin, polyimide resin, or the like within the spirit and the scope of the disclosure. In an embodiment, the pixel defining layer PDL may include light absorbing material or be coated with light absorbent, so that the pixel defining layer PDL can function to absorb light introduced from the outside. For example, the pixel defining layer PDL may include carbon-based black pigment, but is not limited thereto.

The pixel defining layer PDL may include openings that expose given respective areas of the first pixel electrode PE1, the second pixel electrode PE2, and the third pixel electrode PE3, and may protrude from the via layer VIA along a periphery of each of the first to third emission areas EMA1, EMA2, and EMA3 in a third direction DR3.

The emission layer EML may be disposed on each of the first, second, and third pixel electrode PE1, PE2, and PE3 that are exposed through the openings of the pixel defining layer PDL. For example, the first emission layer EML1 may be disposed on the first pixel electrode PE1 that is exposed through the corresponding opening of the pixel defining layer PDL. The second emission layer EML2 may be disposed on the second pixel electrode PE2 that is exposed through the corresponding opening of the pixel defining layer PDL. The third emission layer EML3 may be disposed on the third pixel electrode PE3 that is exposed through the corresponding opening of the pixel defining layer PDL.

The first emission layer EML1 may be positioned on the first pixel electrode PE1 in the corresponding opening of the pixel defining layer PDL. The second emission layer EML2 may be positioned on the second pixel electrode PE2 in the corresponding opening of the pixel defining layer PDL. The third emission layer EML3 may be positioned on the third pixel electrode PE3 in the corresponding opening of the pixel defining layer PDL. Each of the first emission layer EML1, the second emission layer EML2, and the third emission layer EML3 may be supplied to a target area of the corresponding sub-pixel SPX (for example, the pixel electrode that is exposed through the corresponding opening of the pixel defining layer PDL) by an inkjet printing method or the like, but the embodiments are not limited thereto.

Each of the first emission layer EML1, the second emission layer EML2, and the third emission layer EML3 may have a multilayer thin-film structure including a light generation layer configured to generate light. For example, each of the first, second, and third emission layers EML1, EML2, and EML3 may include a light generation layer configured to generate and emit blue light. Each of the first, second, and third emission layers EML1, EML2, and EML3 may include at least one of a hole transport material, a hole injection material, an electron transport material, and an electron injection material.

The common electrode CE may be disposed on the first, second, and third emission layers EML1, EML2, and EML3. The common electrode CE may be provided in common to the first to third sub-pixels SPX1, SPX2, and SPX3. The common electrode CE may be provided in the form of a plate over the overall area of the display area (refer to “DA” in FIG. 1), but is not limited thereto. The common electrode CE may be a thin-film metal layer having a thickness sufficient to allow transmission of blue light emitted from each of the first to third emission layers EML1, EML2, and EML3. The common electrode CE may be made of a metal material having a relatively small thickness, or a transparent conductive material. For example, the common electrode CE may include at least one of various transparent conductive materials including indium tin oxide, indium zinc oxide, indium tin zinc oxide, aluminum zinc oxide, gallium zinc oxide, zinc tin oxide, or gallium tin oxide, and may be substantially transparent or translucent to provide satisfactory transmittance. Hence, blue light emitted from each of the first to third emission layers EML1, EML2, and EML3 that are positioned under or below the common electrode CE may pass through the common electrode CE and be emitted in the upward direction of the encapsulation layer TFE.

The encapsulation layer TFE may include a first encapsulation layer ENC1, a second encapsulation layer ENC2, and a third encapsulation layer ENC3 that are successively positioned on the common electrode CE. The first encapsulation layer ENC1 may be disposed on the display element layer DPL (or the common electrode CE), and positioned over the display area DA and at least a portion of the non-display area NDA. The second encapsulation layer ENC2 may be formed on the first encapsulation layer ENC1, and positioned over the display area DA and at least a portion of the non-display area NDA. The third encapsulation layer ENC3 may be formed on the second encapsulation layer ENC2, and positioned over the display area DA and at least a portion of the non-display area NDA. In an embodiment, the third encapsulation layer ENC3 may be positioned over the display area DA and the entirety of the non-display area NDA.

Each of the first and third encapsulation layers ENC1 and ENC3 may be formed of an inorganic layer including inorganic material. The second encapsulation layer ENC2 may be formed of an organic layer including organic material. The inorganic layer may include, for example, silicon nitride (SiNₓ), silicon oxide (SiOₓ), or silicon oxynitride (SiOₓN_{y}). The organic layer may include organic insulating material such as polyacrylate resin, epoxy resin, phenolic resin, polyamide resin, polyimide resin, unsaturated polyester resin, polyphenylene resin, polyphenylene sulfide resin, or benzocyclobutene (BCB).

The color conversion layer CCL may be disposed on the encapsulation layer TFE. The color conversion layer CCL may include a bank BNK, first and second color conversion patterns CCP1 and CCP2, and a light scattering pattern LSP.

The bank BNK may be disposed on the encapsulation layer TFE to correspond to the pixel defining layer PDL in the non-emission area NEA. The bank BNK may define respective positions of the first color conversion pattern CCP1, the second color conversion pattern CCP2, and the light scattering pattern LSP, thus defining the first emission area EMA1, the second emission area EMA2, and the third emission area EMA3. The bank BNK may enclose each of the first color conversion pattern CCP1, the second color conversion pattern CCP2, and the light scattering pattern LSP.

The bank BNK may be configured to include at least one light blocking material and/or reflective material and enable light emitted from each of the first color conversion pattern CCP1, the second conversion pattern CCP2, and the light scattering pattern LSP to more reliably travel in the image display direction of the display device DD, thus enhancing the light output efficiency of each pixel PXL.

The first color conversion pattern CCP1 may be positioned on the encapsulation layer TFE to correspond to the first light emitting element LD1. The first color conversion pattern CCP1 may include first color conversion particles QD1 which are dispersed in a matrix material such as base resin. For example, the first color conversion particles QD1 may be red quantum dots, which absorb incident blue light, shift the wavelength of the light according to an energy transition, and emit red light. The first sub-pixel SPX1 may be a red pixel. The first color conversion pattern CCP1 may be disposed in at least the first emission area EMA1.

The second color conversion pattern CCP2 may be positioned on the encapsulation layer TFE to correspond to the second light emitting element LD2. The second color conversion pattern CCP2 may include second color conversion particles QD2 which are dispersed in a matrix material such as base resin. For example, the second color conversion particles QD2 may be green quantum dots, which absorb incident blue light, shift the wavelength of the light according to an energy transition, and emit green light. The second sub-pixel SPX2 may be a green pixel. The second color conversion pattern CCP2 may be disposed in at least the second emission area EMA2.

The light scattering pattern LSP may be positioned on the encapsulation layer TFE to correspond to the third light emitting element LD3. The light scattering pattern LSP may include light scattering particles SCT which are dispersed in a matrix material such as base resin. The light scattering pattern LSP may include light scattering particles SCT formed of material such as silica, but the constituent material of the light scattering particles SCT is not limited thereto. In an embodiment, the light scattering particles SCT may be omitted, and the light scattering pattern LSP formed of transparent polymer may be provided. The third sub-pixel SPX3 may be a blue pixel. The light scattering pattern LSP may be disposed in at least the third emission area EMA3.

A first capping layer CPL1 may be disposed on the color conversion layer CCL, thus protecting the color conversion layer CCL. The first capping layer CPL1 may be, for example, an inorganic insulating layer including inorganic material.

The color filter layer CFL may be disposed on the color conversion layer CCL. The color filter layer CFL may include a color filter CF and a light blocking pattern BM. The color filter CF may include a first color filter CF1, a second color filter CF2, and a third color filter CF3.

The first color filter CF1 may be disposed over the color conversion layer CCL to correspond to the first color conversion pattern CCP1 (or the first emission layer EML1). The second color filter CF2 may be disposed over the color conversion layer CCL to correspond to the second color conversion pattern CCP2 (or the second emission layer EML2). The third color filter CF3 may be disposed over the color conversion layer CCL to correspond to the light scattering pattern LSP (or the third emission layer EML3).

The light blocking pattern BM may be disposed adjacent to the first to third color filters CF1, CF2, and CF3. Furthermore, the light blocking pattern BM may be disposed over the color conversion layer CCL to correspond to the bank BNK (or the pixel defining layer PDL) in the non-emission area NEA. The light blocking pattern BM may include light blocking material. For example, the light blocking pattern BM may include a black matrix, but is not limited thereto. In an embodiment, the light blocking pattern BM may include at least one light blocking material and/or reflective material, and allow light emitted from the color conversion layer CCL to more reliably travel in the image display direction of the display device DD, thus enhancing the light output efficiency. The light blocking pattern BM may prevent the colors of light emitted from the first to third color filters CF1, CF2, and CF3 from being mixed with each other.

Each of the first, second, and third color filters CF1, CF2, and CF3 may include colorant such as dye or pigment, which may absorb wavelengths other than a corresponding color wavelength. The first color filter CF1 may be a red color filter. The second color filter CF2 may be a green color filter. The third color filter CF3 may be a blue color filter. Although in the drawing there is illustrated the case where the color filters CF that are adjacent to each other are spaced apart from each other with the light blocking pattern BM interposed therebetween, the adjacent color filters CF may at least partially overlap each other on the light blocking pattern BM. In an embodiment, the first to third color filters CF1, CF2, and CF3 may be disposed in the non-emission area NEA and overlap each other, thus functioning as a light blocking component for preventing optical interference between adjacent sub-pixels SPX from occurring. The light block pattern BM may be omitted.

An overcoat layer OC may be disposed on the color filter layer CFL. The overcoat layer OC may be disposed on the color filter layer CFL and cover underlying components including the color filter layer CFL. The overcoat layer OC may prevent the color filter layer CFL from being damaged or contaminated by permeation of external impurities such as water or air. Furthermore, the overcoat layer OC may prevent colorants of the color filter layer CFL from diffusing into other components. The overcoat layer OC may include an inorganic insulating layer including inorganic material, but is not limited thereto.

In an embodiment, the intermediate layer CTL may be disposed between the color conversion layer CCL and the color filter layer CFL.

The intermediate layer CTL may be formed through a sequential process on the first capping layer CPL1, which functions to protect the color conversion layer CCL. In an embodiment, the intermediate layer CTL may be an optical filter layer that reflects, toward the color conversion layer CCL, (or blocks) light in some wavelength regions of the visible light region emitted from the color conversion layer CCL and transmits light in other wavelength regions to the color filter layer CFL. For example, the intermediate layer CTL may reflect blue light emitted from the color conversion layer CCL toward the color conversion layer CCL while transmitting red light and/or green light to the color filter layer CFL.

The intermediate layer CTL may include a first layer FL, a second layer, SL, a third layer TL, a fourth layer FOL, and a fifth layer FIL, which are successively stacked on the first capping layer CPL1 in the third direction DR3.

The first layer FL, the third layer TL, and the fifth layer FIL may include a same material. For example, the first layer FL, the third layer TL, and the fifth layer FIL may include conductive material. In an embodiment, each of the first layer FL, the third layer TL, and the fifth layer FIL may be formed of a metal thin-film. For example, each of the first layer FL, the third layer TL, and the fifth layer FIL may be formed as a single layer including at least one of aluminum, silver, molybdenum, chromium, iron, copper, platinum, and gold, or may be formed as a single layer made of an alloy thereof. In an embodiment, each of the first layer FL, the third layer TL, and the fifth layer FIL may have a multilayer structure. Each of the first layer FL, the third layer TL, and the fifth layer FIL may have a thickness of about 30 nm or less in the third direction DR3.

The first layer FL of the first sub-pixel SPX1, the first layer FL of the second sub-pixel SPX2, and the first layer FL of the third sub-pixel SPX3 may include a same conductive material, but the embodiments are not limited thereto. In an embodiment, the first layer FL of the first sub-pixel SPX1, the first layer FL of the second sub-pixel SPX2, and the first layer FL of the third sub-pixel SPX3 may include different conductive materials. The third layer TL of the first sub-pixel SPX1, the third layer TL of the second sub-pixel SPX2, and the third layer TL of the third sub-pixel SPX3 may include a same conductive material, but the embodiments are not limited thereto. In an embodiment, the third layer TL of the first sub-pixel SPX1, the third layer TL of the second sub-pixel SPX2, and the third layer TL of the third sub-pixel SPX3 may include different conductive materials. The fifth layer FIL of the first sub-pixel SPX1, the fifth layer FIL of the second sub-pixel SPX2, and the fifth layer FIL of the third sub-pixel SPX3 may include a same conductive material, but the embodiments are not limited thereto. In an embodiment, the fifth layer FIL of the first sub-pixel SPX1, the fifth layer FIL of the second sub-pixel SPX2, and the fifth layer FIL of the third sub-pixel SPX3 may include different conductive materials.

The second layer SL and the fourth layer FOL may include a same material. For example, each of the second layer SL and the fourth layer FOL may be an organic layer including organic material, or an inorganic layer including inorganic material. For example, each of the second layer SL and the fourth layer FOL may include at least one of a transparent organic layer, titanium oxide, silicon oxide, silicon nitride, and silicon oxynitride. In an embodiment, the second layer SL and the fourth layer FOL may include transparent conductive oxide such as indium tin oxide or indium zinc oxide.

In the third direction DR3, a thickness d1 of the first layer FL, a thickness d3 of the third layer TL, and a thickness d5 of the fifth layer FIL may be the same as each other. However, the embodiments are not limited to the aforementioned example. In an embodiment, the thickness d1 of the first layer FL, the thickness d3 of the third layer TL, and the thickness d5 of the fifth layer FIL may be different from each other in the third direction DR3. In an embodiment, at least two of the thickness d1 of the first layer FL, the thickness d3 of the third layer TL, and the thickness d5 of the fifth layer FIL in the third direction DR3 may be the same as each other, and the other may be different from the two.

In an embodiment, a refractive index of each of the second layer SL and the fourth layer FOL may range from about 1.3 to about 2.5. Each of the second layer SL and the fourth layer FOL may have a thickness of about 1 μm or less. The thickness d2 of the second layer SL and the thickness d4 of the fourth layer FOL may be the same as each other in the third direction DR3. However, the embodiments are not limited to the aforementioned example. In an embodiment, the thickness d2 of the second layer SL and the thickness d4 of the fourth layer FOL may be different from each other in the third direction DR3. In the case where the thickness d2 of the second layer SL and the thickness d4 of the fourth layer FOL are different from each other, one of the second and fourth layers SL and FOL may be designed to not have a thickness more than twice that of the other layer.

The second layer SL, which is a dielectric layer, may be placed between the first layer FL and the third layer TL, each of which is formed of a metal thin-film. Furthermore, the fourth layer FOL, which is a dielectric layer, may be placed between the third layer TL and the fifth layer FIL, each of which is formed of a metal thin-film. The interlayer layer CTL including the first layer FL, the second layer SL, the third layer TL, the fourth layer FOL, and the fifth layer FIL, which may be sequentially stacked each other, may be configured as a dual Fabry-Perot cavity structure with a metal (mirror or semi-mirror)-dielectric-metal (mirror or semi-mirror)-dielectric-metal (mirror or semi-mirror) configuration. The first layer FL, the third layer TL, and the fifth layer FIL each formed of a metal thin-film may function as a half-mirror, and each of the second layer SL and the fourth layer FOL may function as a medium that determine wavelength-dependent transmittance and reflectance using the refractive index and the thickness. Making the second layer SL and the fourth layer FOL, each of which functions as a medium, different in thickness, may extend a wavelength band in which the resonance effect of the intermediate layer CTL occurs.

The intermediate layer CTL including the first layer FL, the second layer SL, the third layer TL, the fourth layer FOL, the fifth layer FIL, which may be sequentially stacked each other, may be configured to selectively reflect light in a given wavelength range emitted from the color conversion layer CCL and traveling toward the intermediate layer CTL. For example, the intermediate layer CTL may reflect about 60% or more of light of a wavelength range from about 420 nm to about 480 nm (for example, light of a first wavelength band) emitted from the color conversion layer CCL and traveling toward the intermediate layer CTL, thus directing the reflected light toward the color conversion layer CCL.

In the first sub-pixel SPX1, the intermediate layer CTL may reflect about 60% or more of the light of the first wavelength band traveling toward the intermediate layer CTL rather than reacting with the first color conversion pattern CCP1, back toward the first color conversion pattern CCP1 to induce a reaction with the first color conversion pattern CCP1. The light of the first wavelength band reflected toward the first color conversion pattern CCP1 may react with the first color conversion particles QD1, and thus be emitted as red light. The recycling rate of light of the first wavelength band (for example, blue light) in the first color conversion pattern CCP1 may increase, thus resulting in an increase in the red light emitted from the first color conversion pattern CCP1. Hence, the light output efficiency of the first color conversion pattern CCP1 may be improved.

In the second sub-pixel SPX2, the intermediate layer CTL may reflect about 60% or more of the light of the first wavelength band traveling toward the intermediate layer CTL rather than reacting with the second color conversion pattern CCP2, back toward the second color conversion pattern CCP2 to induce a reaction with the second color conversion pattern CCP2. The light of the first wavelength band reflected toward the second color conversion pattern CCP2 may react with the second color conversion particles QD2, and thus be emitted as green light. The recycling rate of light of the first wavelength band (for example, blue light) in the second color conversion pattern CCP2 may increase, thus resulting in an increase in the green light emitted from the second color conversion pattern CCP2. Hence, the light output efficiency of the second color conversion pattern CCP2 may be improved.

In an embodiment, the intermediate layer CTL transmits light of a second wavelength band and light of a third wavelength band, which are different from the light of the first wavelength band, to the color filter layer CFL. The light of the second wavelength band may be light ranging from about 520 nm to about 580 nm (for example, green light). The light of the third wavelength band may be light ranging from about 620 nm to about 680 nm (for example, red light).

In the first sub-pixel SPX1, the intermediate layer CTL may transmit red light (for example, light in the third wavelength band), reacting with the first color conversion pattern CCP1 and traveling toward the intermediate layer CTL, to the first color filter CF1 of the color filter layer CFL. For example, the transmittance of the red light in the intermediate layer CTL may be less than about 60%, the absorptance of the red light may be less than about 5%, and the rest may be the reflectance of the red light. In other words, the intermediate layer CTL may transmit less than about 60% of incident red light, absorb less than about 5%, and reflect the remainder. However, the embodiments are not limited to the aforementioned example. In an embodiment, the intermediate layer CTL may transmit about 60% or more of the red light to the first color filter CF1 of the color filter layer CFL, absorb less than about 5% of the red light, and reflect the rest of the red light toward the first color conversion pattern CCP1.

In the second sub-pixel SPX2, the intermediate CTL transmits green light (for example, light in the second wavelength band), reacting with the second color conversion pattern CCP2 and traveling toward the intermediate layer CTL, to the second color filter CF2 of the color filter layer CFL. For example, the transmittance of the green light in the intermediate layer CTL may be less than about 60%, the absorptance of the green light may be less than about 5%, and the rest may be the reflectance of the green light. In other words, the intermediate layer CTL may transmit less than about 60% of incident green light, absorb less than about 5%, and reflect the remainder. However, the embodiments are not limited to the aforementioned example. In an embodiment, the intermediate layer CTL may transmit about 60% or more of the green light to the second color filter CF2 of the color filter layer CFL, absorb less than about 5% of the green light, and reflect the rest of the green light toward the second color conversion pattern CCP2.

In the aforementioned embodiment, the intermediate layer CTL may reflect about 60% or more of incident blue light toward the color conversion layer CCL, thus increasing the recycling rate of the blue light. The intermediate layer CTL may transmit about 60% or more of the incident red light to the color filter layer CFL, and transmit about 60% or more of the incident green light to the color filter layer CFL, thus reducing loss of the red light and the green light. The characteristics of the intermediate layer CTL, which may reflect about 60% or more of blue light and allow about 60% or more of each of red light and green light to pass therethrough, may be adjusted based on the thickness and material of each of the first, second, third, fourth, and fifth layers FL, SL, TL, FOL, and FIL.

A second capping layer CPL2 may be disposed on the intermediate layer CTL. The second capping layer CPL2 may be positioned between the intermediate layer CTL and the color filter layer CFL, thus protecting the intermediate layer CTL. The second capping layer CPL2 may be, for example, an inorganic insulating layer including inorganic material, but the embodiments are not limited thereto.

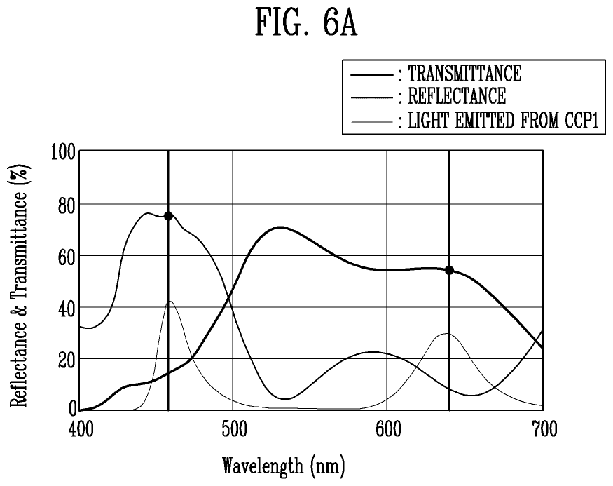

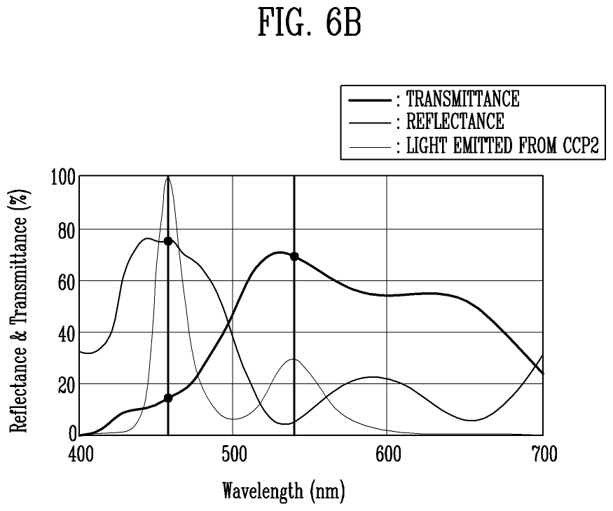

Hereinafter, the transmittance and reflectance of the intermediate layer CTL for each wavelength band will be described with reference to FIGS. 6A and 6B.

FIG. 6A is a graph depicting simulation results of light emitted from the intermediate layer disposed on the first color conversion pattern CCP1 of FIG. 4. FIG. 6B is a graph depicting simulation results of light emitted from the intermediate layer disposed on the second color conversion pattern CCP2 of FIG. 4. The graphs in FIGS. 6A and 6B represent the results of characteristic evaluation of an intermediate layer placed on the first color conversion pattern and the second color conversion pattern, respectively, the intermediate layer including a first layer (a metal thin-film) with a thickness of about 10 nm, a second layer (a dielectric) with a thickness of about 90 nm, a third layer (a metal thin-film) with a thickness of about 15 nm, a fourth layer (a dielectric) with a thickness of about 85 nm, and a fifth layer (a metal thin-film) with a thickness of about 10 nm.

Referring to FIGS. 1 to 6A, the first color conversion pattern (refer to “CCP1” in FIG. 4) may emit light of a wavelength ranging from about 620 nm to about 690 nm (for example, light in the red spectrum). Furthermore, the first color conversion pattern CCP1 may emit light of a wavelength ranging from about 420 nm to about 480 nm (for example, light in the blue spectrum). The light in the blue spectrum may be light that does not react with the first color conversion particles (refer to “QD1” in FIG. 4) of the first color conversion pattern CCP1. The intermediate layer (refer to “CTL” in FIG. 4) on the first color conversion pattern CCP1 may transmit about 54% of the red spectrum light with a wavelength of about 630 nm emitted from the first color conversion pattern CCP1 and reflect about 9% of the light. Furthermore, the intermediate layer CTL may reflect about 75% of the blue spectrum light with a wavelength of about 460 nm emitted from the first color conversion pattern CCP1 and transmit about 14% of the light.

Referring to FIGS. 1 to 6B, the second color conversion pattern (refer to “CCP2” in FIG. 4) may emit light of a wavelength ranging from about 520 nm to about 580 nm (for example, light in the green spectrum). Furthermore, the second color conversion pattern CCP2 may emit light of a wavelength ranging from about 420 nm to about 480 nm (for example, light in the blue spectrum). The blue spectrum light may be light that does not react with the second color conversion particles (refer to “QD2” in FIG. 4) of the second color conversion pattern CCP2. The intermediate layer CTL on the second color conversion pattern CCP2 may transmit about 68% of the green spectrum light with a wavelength of about 540 nm emitted from the second color conversion pattern CCP2 and reflect about 6% of the light. Furthermore, the intermediate layer CTL may reflect about 75% of the blue spectrum light with a wavelength of about 460 nm emitted from the second color conversion pattern CCP2 and transmit about 14% of the light.

If the intermediate layer CTL including the first layer (refer to “FL” in FIG. 5) with a thickness of about 10 nm, a second layer (refer to “SL” in FIG. 5) with a thickness of 90 nm, a third layer (refer to “TL” in FIG. 5) with a thickness of about 15 nm, a fourth layer (refer to “FOL” in FIG. 5) with a thickness of about 85 nm, and a fifth layer (refer to “FIL” in FIG. 5) with a thickness of about 10 nm, which may be sequentially stacked each other, is disposed on each of the first and second color conversion patterns CCP1 and CCP2, about 60% or more of the blue spectrum light emitted from the first and second color conversion patterns CCP1 and CCP2, respectively, may be reflected to the first and second color conversion patterns CCP1 and CCP2. Consequently, the first color conversion pattern CCP1 may recycle and convert incident blue light into red light, and the second color conversion pattern CCP2 may recycle and convert the incident blue light into green light.

The intermediate layer CTL on the first color conversion pattern CCP1 may transmit about 50% or more of the red spectrum light, thus reducing loss of the red spectrum light emitted from the first color conversion pattern CCP1 (or converted in the first color conversion pattern CCP1). The intermediate layer CTL on the second color conversion pattern CCP2 may transmit about 60% or more of the green spectrum light, thus reducing loss of the green spectrum light emitted from the second color conversion pattern CCP2 (or converted in the second color conversion pattern CCP2).

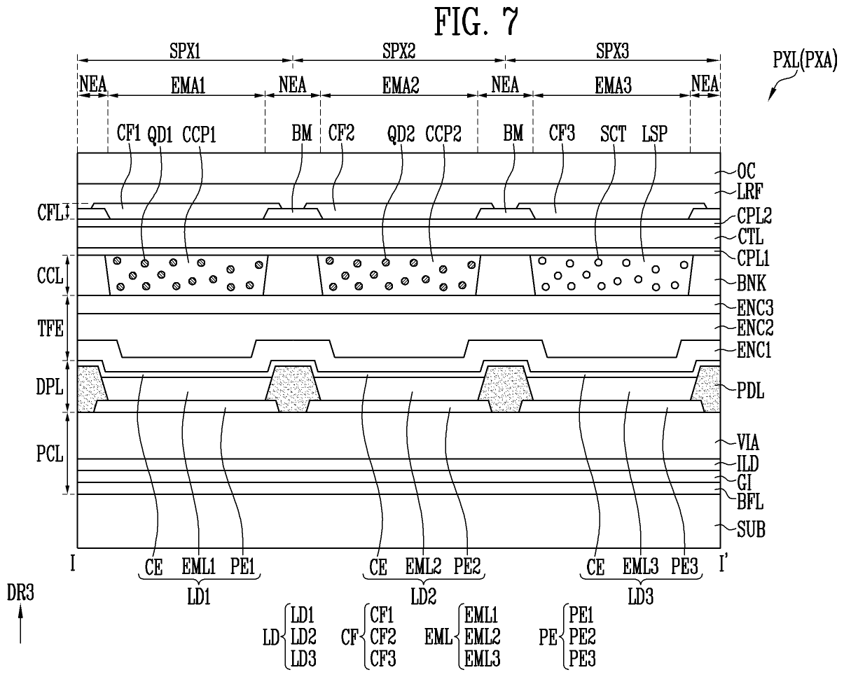

FIG. 7 illustrates a pixel PXL in accordance with an embodiment, and is a schematic sectional view corresponding to line I-I′ of FIG. 1.

With regard to the embodiment of FIG. 7, the following description will be focused on differences from that of the foregoing embodiments, to avoid redundant explanation.

Referring to FIGS. 1 to 7, the pixel PXL may further include a low-reflective film LRF positioned between the color filter layer CFL and the overcoat layer OC.

The low-reflective film LRF may induce destructive interference between light that is incident into the display device (refer to “DD” in FIG. 1) (or pixel PXL) and light that is reflected by the underlying metal, thus reducing reflectance of external light. For example, the low-reflective film LRF may cause destructive interference between light reflected by an upper surface of the low-reflective film LRF and light reflected by an upper surface of the common electrode CE, thus inducing extinction of the light. The low-reflective film LRF may reduce the reflectance of external light, thus enhancing the display quality and the visibility of the display device DD.

The low-reflective film LRF may include inorganic material with relatively low reflectance and, for example, may include metal or metal oxide. In the case where the low-reflective film LRF includes metal, the metal may include, for example, ytterbium (Yb), bismuth (Bi), cobalt (Co), molybdenum (Mo), titanium (Ti), zirconium (Zr), aluminum (Al), chromium (Cr), niobium (Nb), platinum (Pt), tungsten (W), indium (In), tin (Sn), iron (Fe), nickel (Ni), tantalum (Ta), manganese (Mn), zinc (Zn), germanium (Ge), silver (Ag), magnesium (Mg), gold (Au), copper (Cu), calcium (Ca), or combinations thereof. In the case where the low-reflective film LRF includes metal oxide, the metal oxide may include, for example, SiO₂, TiO₂, ZrO₂, Ta₂O₅, HfO₂, Al₂O₃, ZnO, Y₂O₃, BeO, MgO, PbO₂, WO₃, SiNₓ, LiF, CaF₂, MgF₂, CdS or combinations thereof.

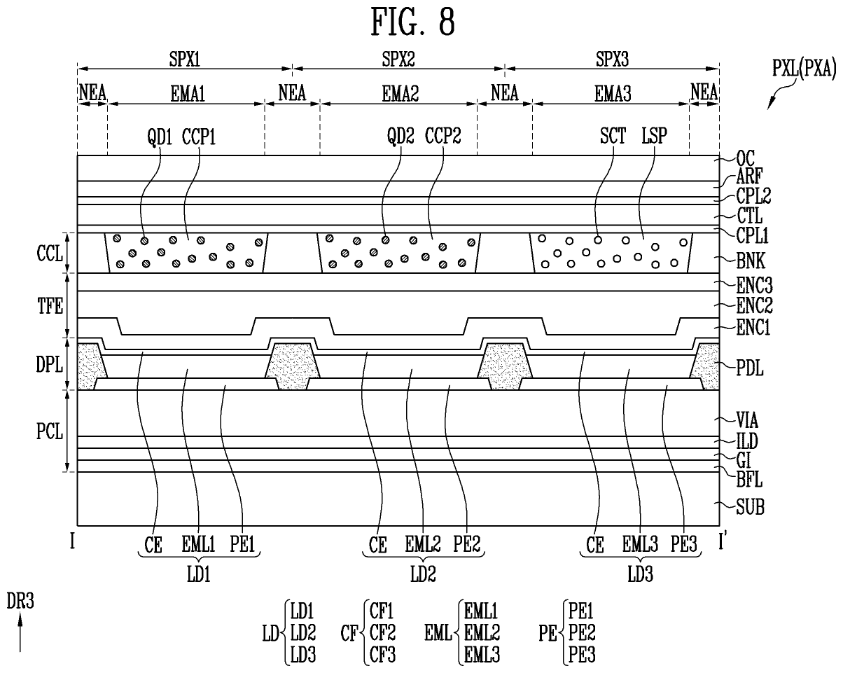

FIG. 8 illustrates a pixel PXL in accordance with an embodiment, and is a schematic sectional view corresponding to line I-I′ of FIG. 1.

With regard to the embodiment of FIG. 8, the following description will be focused on differences from that of the foregoing embodiments, to avoid redundant explanation.

Referring to FIGS. 1 to 3 and 8, the pixel PXL may include a first sub-pixel SPX1, a second sub-pixel SPX2, and a third sub-pixel SPX3. Each of the first, second, and third sub-pixels SPX1, SPX2, and SPX3 may include a substrate SUB, a pixel circuit layer PCL, a display element layer DPL, an encapsulation layer TFE, a color conversion layer CCL, an intermediate layer CTL, an anti-reflection film ARF, and an overcoat layer OC.

The anti-reflection film ARF may be disposed on the intermediate layer CTL between the second capping layer CPL2 and the overcoat layer OC. The anti-reflection film ARF may reduce reflectance of external light that is incident on the display device (refer to “DD” in FIG. 1).

The anti-reflection film ARF may be formed of a polarizing film. The polarizing film may include a linear polarizing layer (or a circular polarizing layer) and a phase delay film such as a quarter-wave plate ( 2/4 plate). The number of phase delay films and a phase delay length of each phase delay film may be determined depending on the operation principle of the anti-reflection film ARF. In an embodiment, the anti-reflection film ARF may include a filter layer including a black matrix and color filters. In an embodiment, the anti-reflection film ARF may include a destructive interference structure. The destructive interference structure may include a first reflective layer and a second reflective layer which are disposed on respective different layers. First reflective light and second reflective light which are respectively reflected by the first reflective layer and the second reflective layer destructively interfere with each other, whereby the reflectance of external light is reduced.

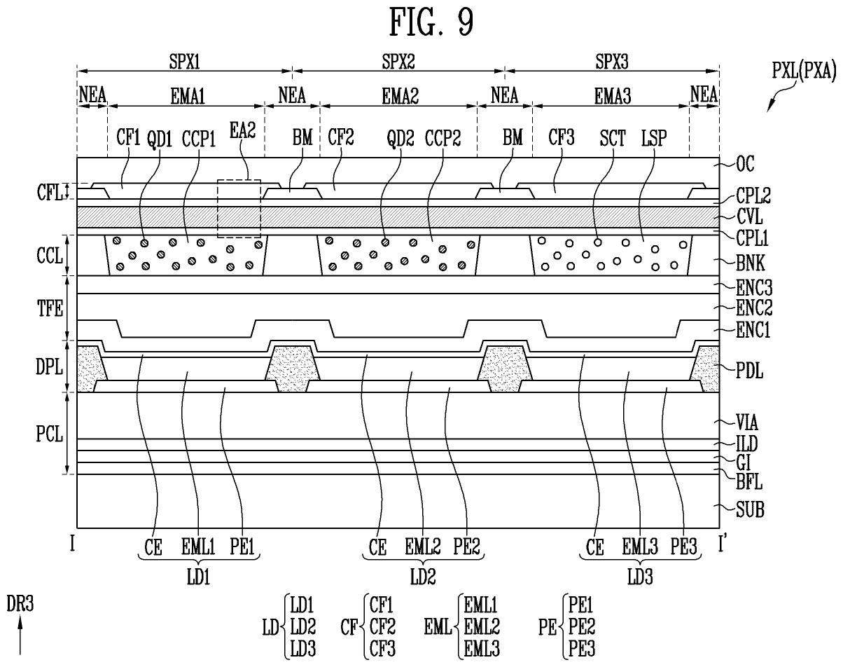

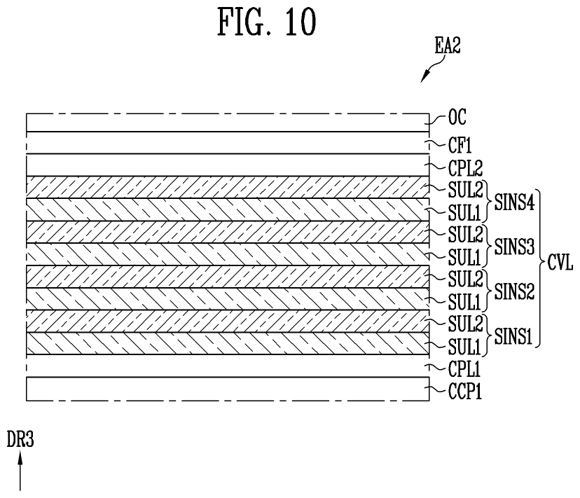

FIG. 9 illustrates a pixel PXL in accordance with an embodiment, and is a schematic sectional view corresponding to line I-I′ of FIG. 1. FIGS. 10 and 11 are schematic enlarged views illustrating portion EA2 of FIG. 9.

The description of the embodiment of FIGS. 9 to 11 will be focused on differences from the above-mentioned embodiments so as to avoid redundant description.

Referring to FIGS. 1 to 3 and 9 to 11, the pixel PXL may include a cover layer CVL disposed between the color conversion layer CCL and the color filter layer CFL. The cover layer CVL may be disposed between a first capping layer CPL1 on the color conversion layer CCL and a second capping layer CPL2 positioned under or below the color filter layer CCL. The first and second capping layers CPL1 and CPL2 are respectively the same as the first and second capping layers CPL1 and CPL2 described with reference to FIG. 4; therefore, further explanation thereof will be omitted.

The cover layer CVL may use a difference in refractive index to recycle light that has not reacted with the color conversion layer CCL (for example, blue light) to react with the color conversion layer CCL, thereby increasing the luminance of the color conversion layer CCL and enhancing the reliability of the display device (refer to “DD” in FIG. 1).

The cover layer CVL may be configured to selectively reflect light in a given wavelength range. The cover layer CVL may be configured to allow light of the first wavelength emitted from the color conversion layer CCL and traveling toward the cover layer CVL to pass through the cover layer CVL, while reflecting light of wavelengths different from the first wavelength. For example, the cover layer CVL may reflect the blue spectrum light emitted from the color conversion layer CCL and traveling toward the cover layer CVL, and transmit the green spectrum light and/or the red spectrum light other than the blue spectrum light to the color filter layer CFL.

The cover layer CVL may include at least one or more sub-insulating layers including a first sub-layer SUL1 and a second sub-layer SUL2, which may be sequentially stacked each other and have different refractive indices. For example, the cover layer CVL may include first, second, third, and fourth sub-insulating layers SINS1, SINS2, SINS3, and SINS4. Each of the first, second, third, and fourth sub-insulating layers SINS1, SINS2, SINS3, and SINS4 may include a first sub-layer SUL1 and a second sub-layer SUL2, which may be sequentially stacked each other in the third direction DR3.

The first sub-layer SUL1 may include a first inorganic layer with a first refractive index. The second sub-layer SUL2 may include a second inorganic layer with a second refractive index different from the first refractive index. The second refractive index may be less than the first refractive index. For example, the first sub-layer SUL1 may be formed of a transparent inorganic layer with a first refractive index of 1.85. The second sub-layer SUL2 may be formed of a transparent inorganic layer with a second refractive index of 1.45. The first sub-layer SUL1 may have a thickness of about 60 nm, and the second sub-layer SUL2 may have a thickness of about 60 nm, but the embodiments are not limited thereto. The first sub-layer SUL1 may include silicon nitride (SiNₓ), and the second layer SUL2 may include silicon oxide (SiOₓ), but the embodiments are not limited thereto.

Each of the first to fourth sub-insulating layers SINS1, SINS2, SINS3, and SINS4 may include a first sub-layer SUL1, and a second sub-layer SUL2 disposed on top of the first sub-layer SUL1 in the third direction DR3. The cover layer CVL may include a distributed Bragg reflection layer formed of a high-refractive-index first sub-layer SUL1 and a low-refractive-index second sub-layer SUL2 that may be alternately stacked each other in a repeating pattern. However, the embodiments are not limited thereto. In an embodiment, as illustrated in FIG. 11, each of the first to fourth sub-insulating layers SINS1, SINS2, SINS3, and SINS4 may include the second sub-layer SUL2, and the first sub-layer SUL1 disposed on top of the second sub-layer SUL2 in the third direction DR3. The cover layer CVL may include a distributed Bragg reflection layer formed of a low-refractive-index second sub-layer SUL2 and a high-refractive-index first sub-layer SUL1 that may be alternately stacked each other in a repeating pattern.

As described above, the cover layer CVL may be formed by alternately stacking the first sub-layer SUL1 and the second sub-layer SUL2 that have different refractive indices, thus forming a repetitive refractive index difference in the cover layer CVL. As a result, light emitted from the color conversion layer CCL and incident on the cover layer CVL may have transmittances varying depending on the angle of incidence. The reflectance of light incident on the cover layer CVL may be increased to an optimized level by adjusting the materials respectively included in the first sub-layer SUL1 and the second sub-layer SUL2 that are stacked, the thicknesses thereof, and/or the number of stacked layers. The thicknesses of the first sub-layer SUL1 and the second sub-layer SUL2 may be adjusted depending on the wavelength and refractive index of light.

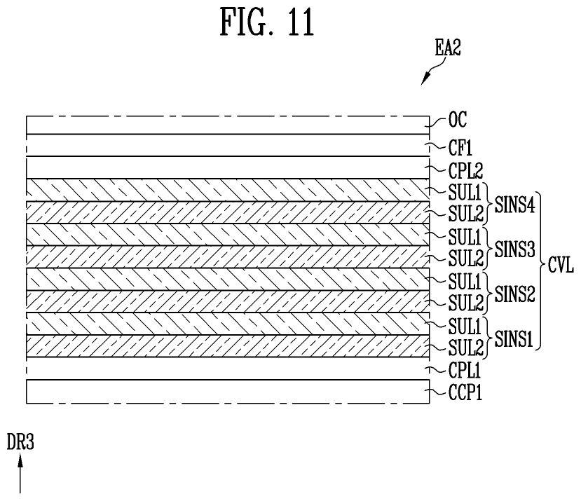

Hereinafter, the reflectance of light passing through the cover layer CVL will be described with reference to FIG. 12 in accordance with embodiments.

FIG. 12 is a graph illustrating the reflectance of light passing through the cover layer of FIG. 10. In FIG. 12, embodiment 1 refers to an embodiment in which the cover (refer to “CVL” in FIG. 10) includes two sub-insulating layers each including the first layer SUL1 and the second layer SUL2 of FIG. 10, embodiment 1 refers to an embodiment in which the cover layer CVL includes three sub-insulating layers, embodiment 3 refers to an embodiment in which the cover layer CVL includes four sub-insulating layers, embodiment 4 refers to an embodiment in which the cover layer CVL includes five sub-insulating layers, and embodiment 5 refers to an embodiment in which the cover layer CVL includes six sub-insulating layers.

Referring to FIGS. 9, 10, and 12, the cover layer CVL corresponding to embodiment 1 reflects less than about 50% of the blue spectrum light with a wavelength range from about 420 nm to about 480 nm, reflects about 20% or more of the green spectrum light with a wavelength range from 520 nm to about 580 nm, and reflects less than about 20% of the red spectrum light with a wavelength range from about 620 nm to about 680 nm. The cover layer CVL corresponding to embodiment 2 may reflect about 60% or more of the blue spectrum light, reflect less than about 40% of the green spectrum light, and reflect less than about 10% of the red spectrum light. The cover layer CVL corresponding to embodiment 3 reflects about 60% or more of the blue spectrum light, reflects less than about 20% of the green spectrum light, and reflect less than about 20% of the red spectrum light. The cover layer CVL corresponding to embodiment 4 reflects about 70% or more of the blue spectrum light, reflects less than about 30% of the green spectrum light, and reflect less than about 10% of the red spectrum light. The cover layer CVL corresponding to embodiment 5 reflects about 70% or more of the blue spectrum light, reflects less than about 20% of the green spectrum light, and reflect less than about 10% of the red spectrum light.

In the case where the cover layer CVL includes at least three or more sub-insulating layers, the cover layer CVL may reflect about 60% or more of the blue spectrum light. In the case where the cover layer CVL includes at least four or more sub-insulating layers, the cover layer CVL may reflect less than about 20% of the green spectrum light. In the case where the cover layer CVL includes at least three or more sub-insulating layers, the cover layer CVL may reflect less than about 20% of the red spectrum light.

If the cover layer CVL including at least three or more sub-insulating layers is disposed between the color conversion layer (refer to “CCL” in FIG. 9) and the color filter layer (refer to “CFL” in FIG. 9), the refractive index difference between the sub-insulating layers may be used so that some of the blue spectrum light incident on the cover layer CVL without reacting with the color conversion layer CCL may be reflected to the color conversion layer CCL and reacted with the color conversion layer CCL. Consequently, the recycling rate of blue light may increase, whereby the light emitting luminance of the color conversion layer CCL may be enhanced.

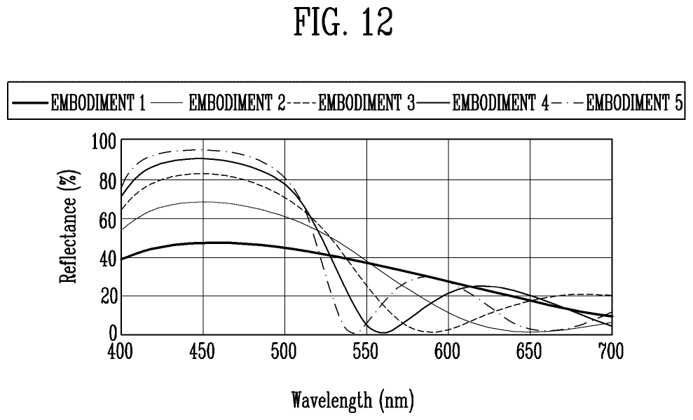

Hereinafter, a pixel PXL using inorganic light emitting diodes (or inorganic light emitting elements) including inorganic light emitting materials as a light source will be described with reference to FIGS. 13 to 18.

FIG. 13 is a schematic circuit diagram illustrating an electrical connection relationship of components included in each of pixels PXL illustrated in FIG. 1. For convenience of description, FIG. 13 illustrates a pixel PXL (or a sub-pixel SPX) that is positioned on the i-th horizontal line (or the i-th pixel row) and connected to the j-th data line Dj.

FIG. 13 illustrates an electrical connection relationship of components included in the pixel PXL that may be employed in an active matrix type display device in accordance with an embodiment. Here, the connection relationship of the components of each pixel PXL is not limited thereto.

Referring to FIGS. 1 to 13, the pixel PXL (or the sub-pixel SPX) may include an emission component EMU configured to generate light with luminance corresponding to a data signal. Furthermore, the pixel PXL may include a pixel circuit PXC configured to drive the emission component EMU.

The emission component EMU may include light emitting elements LD connected in parallel between a first power line PL1 to which a first power voltage VDD is applied and a second power line PL2 to which a second power voltage VSS is applied. Each of the light emitting elements LD may be configured of an inorganic light emitting diode (or an inorganic light emitting element) including inorganic light emitting material.

For example, the emission component EMU may include a first electrode EL1 connected to the pixel circuit PXC and the first power line PL1, a second electrode EL2 connected to the second power line PL2, and light emitting elements LD connected in parallel between the first and second electrodes EL1 and EL2 in the same direction. In an embodiment, the first electrode EL1 may be an anode electrode, and the second electrode EL2 may be a cathode electrode.

Each of the light emitting elements LD included in the emission component EMU may include one end (or the first end) connected to the first power line PL1 by the first electrode EL1, and a remaining end (or the second end) connected to the second power line PL2 by the second electrode EL2. The first power voltage VDD and the second power voltage VSS may have different potentials. For example, the first power voltage VDD may be a high-potential power voltage, and the second power voltage VSS may be a low-potential power voltage. Here, a difference in potential between the first driving power voltage VDD and the second driving power voltage VSS may be set to a value equal to or greater than a threshold voltage of the light emitting elements LD during an emission period of the pixel PXL.

As described above, the light emitting elements LD that are connected in parallel to each other in the same direction (for example, in a forward direction) between the first electrode EL1 and the second electrode EL2 to which different voltages are supplied may form respective valid light sources.

The light emitting elements LD of the emission component EMU may emit light having a luminance corresponding to driving current supplied thereto through the pixel circuit PXC. For example, during each frame period, driving current that corresponds to a grayscale value of a corresponding frame data of the pixel circuit PXC may be supplied to the light emitting component EMU. The driving current supplied to the emission component EMU may be divided into parts which flow into the respective light emitting elements LD. Hence, each of the light emitting elements LD may emit light having a luminance corresponding to current applied thereto, so that the light emitter EMU may emit light having a luminance corresponding to the driving current.

Although there has been described the embodiment in which the opposite ends of the light emitting elements LD are connected in the same direction between the first and second power lines PL1 and PL2, the embodiments are not limited thereto. In an embodiment, the emission component EMU may further include at least one invalid light source, for example, a reverse light emitting element LDr, as well as including the light emitting elements LD that form the respective valid light sources. The reverse light emitting element LDr, along with the light emitting elements LD that form the valid light sources, may be connected in parallel to each other between the first and second electrodes EL1 and EL2. Here, the reverse light emitting element LDr may be connected between the first and second electrodes EL1 and EL2 in a direction opposite to that of the light emitting elements LD. Even in case that a given driving voltage (for example, a normal directional driving voltage) is applied between the first and second electrodes EL1 and EL2, the reverse light emitting element LDr remains disabled. Hence, current substantially does not flow through the reverse light emitting element LDr.

The pixel circuit PXC may be connected to an i-th scan line Si, a j-th data line Dj, an in-th control line CLi, and a j-th sensing line SENj of the display area DA.

The pixel circuit PXC may include first to third transistors T1 to T3, and a storage capacitor Cst.

The first transistor T1 may be a driving transistor configured to control driving current to be applied to the emission component EMU, and may be connected between the first power line PL1 and the emission component EMU. In detail, a first terminal of the first transistor T1 may be connected to the first power line PL1. A second terminal of the first transistor T1 may be connected to a second node N2. A gate electrode of the first transistor T1 may be connected to a first node N1. The first transistor T1 may control, in response to a voltage applied to the first node N1, the amount of driving current to be applied from the first power line PL1 to the emission component EMU through the second node N2. The first terminal of the first transistor T1 may be a drain electrode, and the second terminal of the first transistor T1 may be a source electrode, and the embodiments are not limited thereto. In an embodiment, the first terminal may be a source electrode, and the second terminal may be a drain electrode.

The second transistor T2 may be a switching transistor which selects a pixel PXL (or a sub-pixel SPX) in response to a scan signal and activates the pixel PXL, and may be connected between the j-th data line Dj and the first node N1. A first terminal of the second transistor T2 may be connected to the j-th data line Dj. A second terminal of the second transistor T2 may be connected to the first node N1. A gate electrode of the second transistor T2 may be connected to the i-th scan line Si. The first terminal and the second terminal of the second transistor T2 are different terminals, and, for example, if the first terminal is a drain electrode, the second terminal may be a source electrode.

In case that a scan signal of a gate-on voltage (for example, a high level voltage) is supplied from the i-th scan line Si, the second transistor T2 may be turned on to electrically connect the j-th data line Dj to the first node N1. The first node N1 may be a point at which the second terminal of the second transistor T2 and the gate electrode of the first transistor T1 are connected to each other. The second transistor T2 may transmit a data signal to the gate electrode of the first transistor T1.

The third transistor T3 may acquire a sensing signal through the sensing line SENj by connecting the first transistor T1 to the j-th sensing line SENj, and detect, using the sensing signal, characteristics of the pixel PXL such as a threshold voltage of the first transistor T1. Information about the characteristics of the pixel PXL may be used to convert image data such that a deviation in characteristic between pixels PXL can be compensated for. A second terminal of the third transistor T3 may be connected to the second terminal of the first transistor T1. A first terminal of the third transistor T3 may be connected to the j-th sensing line SENj. A gate electrode of the third transistor T3 may be connected to the i-th control line CLi. Furthermore, the first terminal of the third transistor T3 may be connected to an initialization power supply. The third transistor T3 may be an initialization transistor configured to initialize the second node N2, and may be turned on in case that a sensing control signal is supplied thereto from the i-th control line CLi, so that the voltage of the initialization power supply can be transmitted to the second node N2.

The storage capacitor Cst may include a first storage electrode and a second storage electrode. A first storage electrode of the storage capacitor Cst may be connected to the first node N1. A second storage electrode of the storage capacitor Cst may be connected to the second node N2. The storage capacitor Cst may be charged with a data voltage corresponding to a data signal to be supplied to the first node NI during one frame period. Hence, the storage capacitor Cst may store a voltage corresponding to a difference between a voltage of the gate electrode of the first transistor T1 and a voltage of the second node N2.

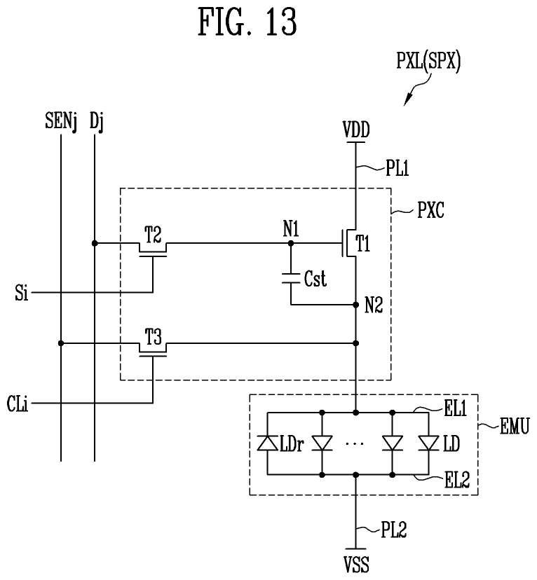

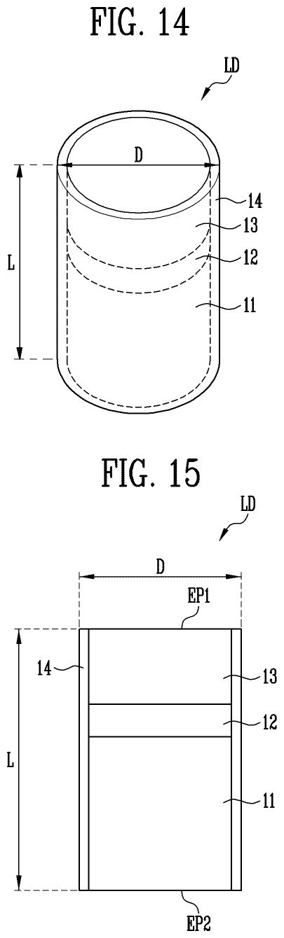

Hereinafter, each light emitting element LD will be described with reference to FIGS. 14 and 15.

FIG. 14 is a schematic perspective view illustrating a light emitting element LD of FIG. 13. FIG. 15 is a schematic sectional view illustrating the light emitting element LD of FIG. 14.

Referring to FIGS. 13 to 15, the light emitting element LD may include a first semiconductor layer 11, a second semiconductor layer 13, and an active layer 12 interposed between the first semiconductor layer 11 and the second semiconductor layer 13. For example, the light emitting element LD may be implemented as an emission stack (or referred to as “light emitting stack pattern”) formed by successively stacking the first semiconductor layer 11, the active layer 12, and the second semiconductor layer 13. The type and/or shape of the light emitting element LD is not limited to that of the embodiment illustrated in FIG. 14.

The light emitting element LD may be formed in a shape extending in one direction or a direction. If the direction in which the light emitting element LD extends is defined as a longitudinal direction, the light emitting element LD may have a first end EP1 and a second end EP2 that are opposite to each other along the longitudinal direction. For example, the second semiconductor layer 13 may be disposed on the first end EPI of the light emitting element LD, and the first semiconductor layer 11 may be disposed on the second end EP2 of the light emitting element LD. However, the embodiments are not limited to the foregoing example.

The light emitting element LD may be provided in various shapes. For example, as illustrated in FIG. 14, the light emitting element LD may have a rod-like shape, a bar-like shape, or a pillar-like shape which is long in the longitudinal direction (for example, has an aspect ratio greater than 1). The light emitting element LD may include a light emitting diode (LED) fabricated to have a subminiature size, for example, with a diameter D and/or a length L corresponding to a range from the nano-scale (or the nanometer scale) to the micro-scale (or the micrometer scale).

In the case where the light emitting element LD is long with respect to the longitudinal direction, the diameter D of the light emitting element LD may range from about 0.5 μm to about 6 μm, and the length L thereof may range from about 1 μm to about 10 μm. However, the diameter D and the length L of the light emitting element LD are not limited thereto. The size of the light emitting element LD may be changed to meet requirements (or design conditions) of a lighting device or a self-emissive display device to which the light emitting element LD is applied.

The first semiconductor layer 11 may include, for example, at least one n-type semiconductor layer. For instance, the first semiconductor layer 11 may include an n-type semiconductor layer which includes at least one semiconductor material of InAlGaN, GaN, AlGaN, InGaN, AlN, and InN and is doped with a first conductive dopant (or an n-type dopant) such as Si, Ge, or Sn. However, the constituent material of the first semiconductor layer 11 is not limited to thereto, and various other materials may be used to form the first conductive semiconductor layer 11.

The active layer 12 (or an emission layer) may be disposed on the first semiconductor layer 11 and have a single or multiple quantum well structure. For example, in the case in which the active layer 12 has a multiple quantum well structure, the active layer 12 may be formed by periodically repeatedly stacking a barrier layer, a stain reinforcing layer, and a well layer as one unit. However, the structure of the active layer 12 is not limited to that of the foregoing embodiment.

The active layer 12 may emit light having a wavelength ranging from about 400 nm to about 900 nm, and have a double hetero structure. In an embodiment, a clad layer doped with a conductive dopant may be formed over or under or below the active layer 12 along the longitudinal direction of the light emitting element LD. For example, the clad layer may be formed of an AlGaN layer or an InAlGaN layer. In an embodiment, material such as AlGaN or InAlGaN may be used to form the active layer 12, and various other materials may be used to form the active layer 12.

If an electric field having a given voltage or more is applied to the opposite ends of the light emitting element LD, the light emitting element LD may emit light by coupling of electron-hole pairs in the active layer 12. Since light emission of the light emitting element LD can be controlled based on the foregoing principle, the light emitting element LD may be used as a light source (a light emitting source) of various light emitting devices as well as a pixel of a display device.

The second semiconductor layer 13 may be disposed on the active layer 12 and include a semiconductor layer of a type different from that of the first semiconductor layer 11. For example, the second semiconductor layer 13 may include at least one p-type semiconductor layer. For instance, the second semiconductor layer 13 may include a p-type semiconductor layer which includes at least one semiconductor material of InAlGaN, GaN, AlGaN, InGaN, AlN, and InN, and is doped with a second conductive dopant (or a p-type dopant) such as Mg, Zn, Ca, Sr, or Ba. However, the material for forming the second semiconductor layer 13 is not limited thereto, and various other materials may be used to form the second semiconductor layer 13.

The first semiconductor layer 11 and the second semiconductor layer 13 may have different thicknesses in the longitudinal direction of the light emitting element LD. For example, the first semiconductor layer 11 may have a thickness greater than that of the second semiconductor layer 13 in the longitudinal direction of the light emitting element LD, but the embodiments are not limited thereto.

Although FIGS. 14 and 15 illustrate that each of the first semiconductor layer 11 and the second semiconductor layer 13 is formed of a single layer, the embodiments are not limited thereto. In an embodiment, depending on the material of the active layer 12, each of the first semiconductor layer 11 and the second semiconductor layer 13 may further include at least one or more layers, for example, a clad layer and/or a tensile strain barrier reducing (TSBR) layer.

In an embodiment, the light emitting element LD may further include a contact electrode (hereinafter referred to as “first contact electrode”) disposed over the second semiconductor layer 13, as well as including the first semiconductor layer 11, the active layer 12, and the second semiconductor layer 13. Furthermore, in an embodiment, the light emitting element LD may further include an additional contact electrode (hereinafter referred to as “second contact electrode”) disposed on one end or an end of the first semiconductor layer 11.

Each of the first and second contact electrodes may be an ohmic contact electrode, but the embodiments are not limited thereto. In an embodiment, each of the first and second contact electrodes may be a Schottky contact electrode.

Materials included in the first and second contact electrodes may be identical to or different from each other. The first and second contact electrodes may be substantially transparent or translucent.

In an embodiment, the light emitting element LD may further include an insulating layer 14. However, depending on the embodiment, the insulating layer 14 may be omitted, or may be provided to cover only some of the first semiconductor layer 11, the active layer 12, and the second semiconductor layer 13.

The insulating layer 14 may prevent the active layer 12 from short-circuiting due to making contact with conductive material except the first and second semiconductor layers 11 and 13. Furthermore, the insulating layer 14 may minimize a surface defect of the light emitting element LD, thus enhancing the lifetime and emission efficiency of the light emitting element LD. In the case in which light emitting elements LD are disposed in close contact with each other, the insulating layer 14 may prevent an undesired short-circuit from occurring between the light emitting elements LD. The presence or non-presence of the insulating layer 14 is not limited, so long as the active layer 12 can be prevented from short-circuiting with external conductive material.

The insulating layer 14 may be provided to enclose an overall outer circumferential surface of the emission stack including the first semiconductor layer 11, the active layer 12, and the second semiconductor layer 13, but is not limited thereto.

The insulating layer 14 may include transparent insulating material. Various materials having insulation properties may be used as the material of the insulating layer 14. The insulating layer 14 may have a single-layer structure or a multilayer structure including a double-layer structure.

In an embodiment, the light emitting element LD may be implemented as a light emitting pattern having a core-shell structure.

The light emitting element LD may be employed as a light emitting source (or a light source) for various display devices. The light emitting element LD may be fabricated through a surface treatment process.

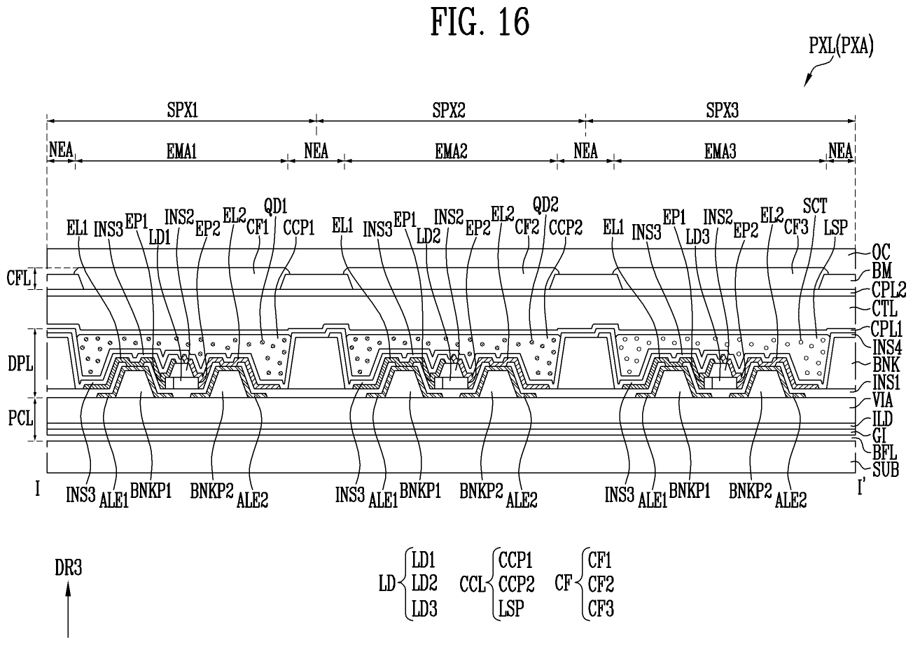

FIG. 16 is a schematic sectional view taken along line I-I′ of FIG. 1.

With regard to the embodiment of FIG. 16, the following description will be focused on differences from that of the foregoing embodiments, to avoid redundant explanation.

Referring to FIGS. 1, and 13 to 15, the pixel PXL may be disposed in a pixel area PXA in the display area DA. The pixel PXL may include a first sub-pixel SPX1, a second sub-pixel SPX2, and a third sub-pixel SPX3. The first sub-pixel SPX1 may be a red pixel. The second sub-pixel SPX2 may be a green pixel. The third sub-pixel SPX3 may be a blue pixel.

The pixel area PXA may include a first emission area EMA1, a second emission area EMA2, a third emission area EMA3, and a non-emission area NEA. The first emission area EMA1 may be an emission area of the first sub-pixel SPX1. The second emission area EMA2 may be an emission area of the second sub-pixel SPX2. The third emission area EMA3 may be an emission area of the third sub-pixel SPX3.

Each of the first, second, and third sub-pixels SPX1, SPX2, and SPX3 may include a substrate SUB, a pixel circuit layer PCL, a display element layer DPL, an intermediate layer CTL, a color filter layer CFL, and an overcoat layer OC.

The pixel circuit layer PCL may be disposed on the substrate SUB. In the pixel circuit layer PCL, circuit elements that form the pixel circuit (refer to “PXC” in FIG. 13) of each of the first to third sub-pixels SPX1, SPX2, and SPX3, and signal lines electrically connected to the circuit elements, may be disposed. The buffer layer BFL, the gate insulating layer GI, the interlayer insulating layer ILD, and the via layer VIA may be disposed in the pixel circuit layer PCL.

The display element layer DPL may be disposed on the pixel circuit layer PCL. In the display element layer DPL, there may be disposed first and second bank patterns BNKP1 and BNKP2, a bank BNK, first and second alignment electrodes ALE1 and ALE2, a light emitting element LD, first and second electrodes EL1 and EL2, and a color conversion layer CCL. Furthermore, first, second, third, and fourth insulating layers INS1, INS2, INS3, and INS4 may be disposed in the display element layer DPL.

Each of the first and second bank patterns BNKP1 and BNKP2 may be provided and/or formed on the pixel circuit layer PCL (or the via layer VIA), and may be positioned in each of the first, second, and third emission areas EMA1, EMA2, and EMA3. The first and second bank patterns BNKP1 and BNKP2 may respectively support the first and second alignment electrodes ALE1 and ALE2 to change a surface profile (or a surface shape) of each of the first and second alignment electrodes ALE1 and ALE2 so that light emitted from the light emitting element LD can be guided in an image display direction of the display panel DD. Each of the first and second bank patterns BNKP1 and BNKP2 may be an inorganic insulating layer made of inorganic material or an organic insulating layer made of organic material. Each of the first and second bank patterns BNKP1 and BNKP2 may include an organic insulating layer having a single-layer structure and/or an inorganic insulating layer having a single-layer structure, but the embodiments are not limited thereto.

Each of the first and second alignment electrodes ALE1 and ALE2 may have a protrusion that is provided and/or formed on the corresponding bank pattern and protrudes from the via layer VIA in the third direction DR3. For example, the first alignment electrode ALE1 may have a protrusion that is provided and/or formed on the first bank pattern BNKP1 and protrudes from the via layer VIA in the third direction DR3. The second alignment electrode ALE2 may include a protrusion that is provided and/or formed on the second bank pattern BNKP2 and protrudes from the via layer VIA in the third direction DR3. Each of the first and second alignment electrodes ALE1 and ALE2 may include conductive material having a reflectance to allow light emitted from the light emitting element LD to travel in the image display direction of the display device DD. The first alignment electrode ALE1 may be electrically connected to the pixel circuit PXC disposed in the pixel circuit layer PCL. The second alignment electrode ALE2 may be electrically connected to the second power line (refer to “PL2” in FIG. 13) disposed in the pixel circuit layer PCL.

The first insulating layer INS1 may be disposed on the first and second alignment electrodes ALE1 and ALE2. The first insulating layer INS1 may be partially open to allow components disposed thereunder to be exposed. For example, the first insulating layer INS1 may be partially open to allow a portion of each of the first and second alignment electrodes ALE1 and ALE2 to be exposed. The first insulating layer INS1 may be formed of an inorganic insulating layer including inorganic material, or an organic insulating layer including organic material. For example, the first insulating layer INS1 may include at least one of silicon nitride (SiNₓ), silicon oxide (SiOₓ), silicon oxynitride (SiOₓN_{y}), and aluminum oxide (AlOₓ), but the embodiments are not limited thereto.

The bank BNK may be provided and/or formed on the first insulating layer INS1.

The bank BNK may be provided on the first insulating layer INS1 in the non-emission area NEA, and may define (or partition) the first emission area EMA1, the second emission area EMA2, and the third emission area EMA3. At the step of inputting (supplying) the light emitting elements LD to each of the first, second, and third emission areas EMA1, EMA2, and EMA3, the bank BNK may function as a dam structure configured to prevent a solution mixed with the light emitting elements LD from being drawn into an adjacent sub-pixel SPX or control the amount of solution such that a constant amount of solution is supplied to each emission area. Furthermore, the bank BNK may define respective positions of the first color conversion pattern CCP1, the second color conversion pattern CCP2, and the light scattering pattern LSP, thus defining the first emission area EMA1, the second emission area EMA2, and the third emission area EMA3. The bank BNK, for example, may enclose each of the first color conversion pattern CCP1, the second color conversion pattern CCP2, and the light scattering pattern LSP. The bank BNK may include at least one light blocking material and/or reflective material, thus preventing a light leakage defect in which light (or a ray) leaks between the first to third sub-pixels SPX1, SPX2, and SPX3.

The light emitting element LD may be supplied to and/or aligned in each of the first to third emission areas EMA1, EMA2, and EMA3. For example, the light emitting element LD may be supplied (or inputted) to each of the first to third emission areas EMA1, EMA2, and EMA3 by an inkjet printing method or the like within the spirit and the scope of the disclosure. The light emitting element LD may be aligned between the first alignment electrode ALE1 and the second alignment electrode ALE2 by a given signal (or an alignment signal) applied to each of the first and second alignment electrodes ALE1 and ALE2. The light emitting element LD may include a first light emitting element LD1 disposed in the first sub-pixel SPX1 (or the first emission area EMA1), a second light emitting element LD2 disposed in the second sub-pixel SPX2 (or the second emission area EMA2), and a third light emitting element LD3 disposed in the third sub-pixel SPX3 (or the third emission area EMA3). First light emitting elements LD1 may be disposed in the first sub-pixel SPX1. Second light emitting elements LD2 may be disposed in the second sub-pixel SPX2. Third light emitting elements LD3 may be disposed in the third sub-pixel SPX3. Each of the first, second, and third light emitting elements LD1, LD2, and LD3 may include a first end EPI and a second end EP2. In an embodiment, the first, second, and third light emitting elements LD1, LD2, and LD3 may emit blue light.

The second insulating layer INS2 may be provided and/or formed on each of the first, second, and third light emitting elements LD1, LD2, and LD3. The second insulating layer INS2 may be provided and/or formed on each of the first, second, and third light emitting elements LD1, LD2, and LD3 and partially cover an outer circumferential surface (or a surface) of each of the first, second, and third light emitting elements LD1, LD2, and LD3, such that the first end EPI and the second end EP2 of each of the first, second, and third light emitting elements LD1, LD2, and LD3 are exposed to the outside. The second insulating layer INS2 may be formed of a single layer or multiple layers, and include an inorganic insulating layer including at least one inorganic material or an organic insulating layer including at least one organic material.

In each of the first, second, and third emission areas EMA1, EMA2, and EMA3, the first electrode EL1 may be disposed on the first end EP1 of each of the first, second, and third light emitting elements LD1, LD2, and LD3, the second insulating layer INS2, and the first insulating layer INS1 on the first alignment electrode ALE1. The first electrode ELI may be electrically connected to the first alignment electrode ALE1 exposed from the first insulating layer INS1.

The third insulating layer INS3 may be provided and/or formed on the first electrode EL1. The third insulating layer INS3 may be formed of an inorganic insulating layer including inorganic material, or an organic insulating layer including organic material. For example, the third insulating layer INS3 may include at least one of silicon nitride (SiNₓ), silicon oxide (SiOₓ), silicon oxynitride (SiOₓN_{y}), and aluminum oxide (AlOₓ), but the embodiments are not limited thereto. In an embodiment, the third insulating layer INS3 may be omitted.

The second electrode EL2 may be disposed on the second end EP2 of each of the first, second, and third light emitting elements LD1, LD2, and LD3, the second insulating layer INS2 of each of the first, second, and third light emitting elements LD1, LD2, and LD3, the first insulating layer INS1 on the second alignment electrode ALE2, and the third insulating layer INS3 on the second insulating layer INS2. The second electrode EL2 may be electrically connected to the second alignment electrode ALE2 exposed from the first insulating layer INS1.

The first electrode EL1 and the second electrode EL2 may be formed through different processes and provided in different layers. However, the embodiments are not limited thereto. In an embodiment, the first electrode EL1 and the second electrode EL2 may be formed through a same process and be provided in a same layer.

The first and second electrodes EL1 and EL2 may be formed of various transparent conductive materials. For example, the first and second electrodes EL1 and EL2 may include at least one of various transparent conductive materials (or substances) including indium tin oxide (ITO), indium zinc oxide (IZO), zinc oxide (ZnOₓ), indium gallium zinc oxide (IGZO), and indium tin zinc oxide (ITZO), and be substantially transparent or translucent to satisfy a selectable transmittancy (or transmissivity).

The fourth insulating layer INS4 may be provided and/or formed on the first and second electrodes EL1 and EL2. The fourth insulating layer INS4 may be an inorganic insulating layer including inorganic material or an organic insulating layer including organic material. For example, the fourth insulating layer INS4 may have a structure formed by alternately stacking at least one inorganic insulating layer and at least one organic insulating layer. In an embodiment, the fourth insulating layer INS4 may be omitted.

The color conversion layer CCL may be disposed on the fourth insulating layer INS4.

The color conversion layer CCL may include first and second color conversion patterns CCP1 and CCP2, and a light scattering pattern LSP. The bank BNK may enclose each of the first color conversion pattern CCP1, the second color conversion pattern CCP2, and the light scattering pattern LSP.

The first color conversion pattern CCP1 may be positioned on the fourth insulating layer INS4 to correspond to the first light emitting element LD1 and absorb incident blue light to emit red light. The first color conversion pattern CCP1 may include first color conversion particles QD1 which are dispersed in a matrix material such as base resin.

The second color conversion pattern CCP2 may be positioned on the fourth insulating layer INS4 to correspond to the second light emitting element LD2 and absorb incident blue light to emit green light. The second color conversion pattern CCP2 may include second color conversion particles QD2 which are dispersed in a matrix material such as base resin.

The light scattering pattern LSP may be positioned on the fourth insulating layer INS4 to correspond to the third light emitting element LD3 and allow incident blue light to pass therethrough without alteration. The light scattering pattern LSP may include light scattering particles SCT which are dispersed in a matrix material such as base resin.

A first capping layer CPL1 may be disposed on the display element layer DPL (or the color conversion layer CCL), thus protecting the display element layer DPL.

An intermediate layer CTL may be provided and/or formed on the first capping layer CPL1. The intermediate layer CTL may be an optical filter layer that reflects, toward the color conversion layer CCL, (or blocks) light in some wavelength regions of the visible light region emitted from the color conversion layer CCL and transmits light in other wavelength regions to the color filter layer CFL. For example, the intermediate layer CTL may reflect some of the blue light emitted from the color conversion layer CCL toward the color conversion layer CCL while transmitting some of the red light and/or some of the green light to the color filter layer CFL. The intermediate layer CTL may be the same as the intermediate layer CTL described with reference to FIGS. 4 and 5. For example, the intermediate layer CTL may include a first layer FL, a second layer, SL, a third layer TL, a fourth layer FOL, and a fifth layer FIL, which may be sequentially stacked each other on the first capping layer CPL1 in the third direction DR3, as illustrated in FIG. 5. The interlayer layer CTL including the first layer FL, the second layer SL, the third layer TL, the fourth layer FOL, and the fifth layer FIL, which may be sequentially stacked each other, may be configured as a dual Fabry-Perot cavity structure with a metal (mirror or semi-mirror)-dielectric-metal (mirror or semi-mirror)-dielectric-metal (mirror or semi-mirror) configuration.

In the first sub-pixel SPX1, the intermediate layer CTL may reflect about 60% or more of the blue light traveling toward the intermediate layer CTL rather than reacting with the first color conversion pattern CCP1, back toward the first color conversion pattern CCP1 to induce a reaction with the first color conversion pattern CCP1. The blue light reflected toward the first color conversion pattern CCP1 may react with the first color conversion particles QDI, and thus be emitted as red light. Consequently, the recycling rate of the blue light in the first color conversion pattern CCP1 may increase, thus improving the light output efficiency of the first color conversion pattern CCP1.

In the first sub-pixel SPX1, the intermediate layer CTL may transmit about 60% or more of the red light, reacting with the first color conversion pattern CCP1 and traveling toward the intermediate layer CTL, to the first color filter CF1 of the color filter layer CFL.

In the second sub-pixel SPX2, the intermediate layer CTL may reflect about 60% or more of the blue light traveling toward the intermediate layer CTL rather than reacting with the second color conversion pattern CCP2, back toward the second color conversion pattern CCP2 to induce a reaction with the second color conversion pattern CCP2. The blue light reflected toward the second color conversion pattern CCP2 may react with the second color conversion particles QD2, and thus be emitted as green light. Consequently, the recycling rate of the blue light in the second color conversion pattern CCP2 may increase, thus improving the light output efficiency of the second color conversion pattern CCP2.

In the second sub-pixel SPX2, the intermediate layer CTL may transmit about 60% or more of the green light, reacting with the second color conversion pattern CCP2 and traveling toward the intermediate layer CTL, to the second color filter CF2 of the color filter layer CFL.

In the aforementioned embodiment, the intermediate layer CTL may reflect about 60% or more of incident blue light toward the color conversion layer CCL, thus increasing the recycling rate of the blue light. Furthermore, the intermediate layer CTL may transmit about 60% or more of red light and about 60% or more of green light to the color filter layer CFL, thus reducing loss of the red light and the green light.

A second capping layer CPL2 may be disposed on the intermediate layer CTL, thus protecting the intermediate layer CTL.

A color filter layer CFL may be provided and/or formed on the second capping layer CPL2. The color filter layer CFL may include a color filter CF and a light blocking pattern BM. The color filter CF may include a first color filter CF1, a second color filter CF2, and a third color filter CF3.

The first color filter CF1 may be disposed on the second capping layer CPL2 to correspond to the first color conversion pattern CCP1 (or the first light emitting element LD1). The second color filter CF2 may be disposed on the second capping layer CPL2 to correspond to the second color conversion pattern CCP2 (or the second light emitting element LD2). The third color filter CF3 may be disposed on the second capping layer CPL2 to correspond to the light scattering pattern LSP (or the third light emitting element LD3).

The light blocking pattern BM may be disposed adjacent to the first to third color filters CF1, CF2, and CF3. Furthermore, the light blocking pattern BM may be disposed on the second capping layer CPL2 to correspond to the bank BNK in the non-emission area NEA. The light blocking pattern BM may include light blocking material.

An overcoat layer OC may be disposed on the color filter layer CFL. The overcoat layer OC may be disposed on the color filter layer CFL and cover underlying components including the color filter layer CFL.

In an embodiment, an intermediate layer including a first layer, a second layer, a third layer, a fourth layer, and a fifth layer (or a cover layer including sub-insulating layers each including a first sub-layer and a second sub-layer having different refractive indices) may be disposed between a color conversion layer (or a QD conversion layer) and a color filter layer, thus reflecting some of blue light emitted from the color conversion layer to the color conversion layer, thereby further enhancing the recycling effect of the blue light in the color conversion layer.

In an embodiment, the intermediate layer is disposed between the color conversion layer and the color filter layer to increase the transmittance of red light and green light emitted from the color conversion layer, thus reducing loss of the red light and the green light.

In an embodiment, light output efficiency of light emitted from the color conversion layer may be improved, whereby there may be provided a display device with enhanced reliability.

The effects of the embodiments are not limited by the foregoing, and other various effects are included herein.

While various one or more embodiments have been described above, those skilled in the art will appreciate that various modifications, additions and substitutions are possible, without departing from the scope of the disclosure.

Therefore, embodiments disclosed in this specification are only for illustrative purposes rather than limiting the technical scope of the disclosure. The scope of the disclosure is also defined by the accompanying claims.

What is claimed is:

1. A display device, comprising:
a light emitting element;
a color conversion layer disposed on the light emitting element, the color conversion layer absorbing light emitted from the light emitting element and emitting one of first color light, second color light, and third color light;
a color filter layer disposed on the color conversion layer, the color filter layer allowing light emitted from the color conversion layer to selectively pass through the color filter layer; and
an intermediate layer disposed between the color conversion layer and the color filter layer, the intermediate layer reflecting a portion of the third color light to the color conversion layer, and transmitting a portion of the first color light and a portion of the second color light to the color filter layer, wherein
the intermediate layer includes a first layer, a second layer, a third layer, a fourth layer, and a fifth layer that are sequentially stacked each other,
each of the first layer, the third layer, and the fifth layer includes a conductive material, and
each of the second layer and the fourth layer includes a material different from the material of each of the first layer, the third layer, and the fifth layer.

2. The display device according to claim 1, wherein
each of the first, layer the third layer, and the fifth layer includes a metal thin-film with a thickness of about 30 nm or less, and
each of the second layer and the fourth layer includes one of an organic insulating layer and an inorganic insulating layer.

3. The display device according to claim 2, wherein each of the second layer and the fourth layer has a refractive index in a range of about 1.3 to about 2.5, and has a thickness of about 1 μm.

4. The display device according to claim 2, wherein the first layer, the second layer, the third layer, the fourth layer, and the fifth layer have different thicknesses.

5. The display device according to claim 2, wherein the second layer and the fourth layer have an identical thickness.

6. The display device according to claim 2, wherein the second layer and the fourth layer have different thicknesses.

7. The display device according to claim 6, wherein one of the second layer and the fourth layer has a thickness less than two times a thickness of another one of the second layer and the fourth layer.

8. The display device according to claim 2, wherein
the first color light includes red light with a wavelength in a range of about 620 nm to about 680 nm,
the second color light includes green light with a wavelength in a range of about 520 nm to about 580 nm, and
the third color light includes blue light with a wavelength in a range of about 420 nm to about 480 nm.

9. The display device according to claim 8, wherein
the intermediate layer reflects about 60% or more of the third color light to the color conversion layer, and transmits about 20% or less of the third color light to the color filter layer,
the intermediate layer transmits about 50% or more of the first color light to the color filter layer, absorbs less than about 5% of the first color light, and reflects a rest of the first color light to the color conversion layer, and
the intermediate layer transmits about 60% or more of the second color light to the color filter layer, absorbs less than about 5% of the second color light, and reflects a remainder of the second color light to the color conversion layer.

10. The display device according to claim 8, wherein the color conversion layer comprises:
a first color conversion pattern including first color conversion particles that absorb light emitted from the light emitting element and emit the red light;
a second color conversion pattern including second color conversion particles that absorb light emitted from the light emitting element and emit the green light; and
a light scattering pattern including light scattering particles that absorb light emitted from the light emitting element and emit the blue light.

11. The display device according to claim 10, wherein
the color filter layer comprises:
a first color filter disposed on the first color conversion pattern;
a second color filter disposed on the second color conversion pattern; and
a third color filter disposed on the light scattering pattern,
the first color filter comprises a red color filter,
the second color filter comprises a green color filter, and
the third color filter comprises a blue color filter.

12. The display device according to claim 1, wherein
the light emitting element comprises an organic light emitting diode,
the organic light emitting diode comprises a pixel electrode disposed on a substrate, an emission layer disposed on the pixel electrode, and a common electrode disposed on the emission layer, and
one of the pixel electrode and the common electrode includes a transparent conductive material, and another one of the pixel electrode and the common electrode includes an opaque conductive material.

13. The display device according to claim 1, wherein
the light emitting element includes a plurality of inorganic light emitting diodes each including a first end and a second end that face each other, and
the plurality of inorganic light emitting diodes comprises:
a first semiconductor layer disposed in the second end and including an n-type semiconductor layer;
a second semiconductor layer disposed in the first end and including a p-type semiconductor layer; and
an active layer disposed between the first semiconductor layer and the second semiconductor layer.

14. The display device according to claim 13, further comprising:
a first electrode electrically connected to the first end of each of the light emitting diodes; and
a second electrode electrically connected to the second end of each of the light emitting diodes,
wherein each of the first electrode and the second electrode includes a transparent conductive material.

15. The display device according to claim 1, further comprising:
a low-reflective layer disposed on the color filter layer.

16. A display device, comprising:
a light emitting element;
a color conversion layer disposed on the light emitting element, the color conversion layer absorbing light emitted from the light emitting element and emitting one of first color light, second color light, and third color light;
a color filter layer disposed on the color conversion layer, the color filter layer allowing light emitted from the color conversion layer to selectively pass through the color filter layer; and
a cover layer disposed between the color conversion layer and the color filter layer,
wherein
the cover layer comprises a plurality of sub-insulating layers each including a first sub-layer and a second sub-layer, and
the first sub-layer and the second sub-layer have different a different refractive index.

17. The display device according to claim 16, wherein
the second sub-layer is disposed on the first sub-layer,
the first sub-layer comprises a first inorganic layer with a first refractive index, and the second sub-layer comprises a second inorganic layer with a second refractive index, and
the first refractive index is greater than the second refractive index.

18. The display device according to claim 16, wherein
the first sub-layer is disposed on the second sub-layer,
the first sub-layer comprises a first inorganic layer with a first refractive index, and the second sub-layer comprises a second inorganic layer with a second refractive index, and
the second refractive index is less than the first refractive index.

19. A display device, comprising:
a light emitting element;
a color conversion layer disposed on the light emitting element, the color conversion layer absorbing light emitted from the light emitting element and emitting one of first color light, second color light, and third color light;
an intermediate layer disposed on the color conversion layer, the intermediate layer reflecting a portion of the third color light to the color conversion layer, and allowing a portion of the first color light and a portion of the second color light to pass through the color conversion layer; and
an anti-reflection film disposed on the intermediate layer, wherein
the intermediate layer includes a first layer, a second layer, a third layer, a fourth layer, and a fifth layer that are sequentially stacked each other,
each of the first layer, the third layer, and the fifth layer includes a conductive material, and
each of the second layer and the fourth layer includes a material different from the material of each of the first layer, the third layer, and the fifth layer.

20. The display device according to claim 19, wherein
each of the first layer, the third layer, and the fifth layer includes a metal thin-film with a thickness of about 30 nm or less, and
each of the second layer and the fourth layer includes one of an organic insulating layer and an inorganic insulating layer.
